(19) United States
(12) Patent Application Publication
(10) Pub. No.: US 2023/0200176 A1
(43) Pub. Date: Jun. 22, 2023

(54) DISPLAY DEVICE AND METHOD OF MANUFACTURING DISPLAY DEVICE

(71) Applicant: Samsung Display Co., LTD., Yongin-si (KR)

(72) Inventors: Jin Woo LEE, Yongin-si (KR); Jeong Nyun KIM, Yongin-si (KR); Sung Geun BAE, Yongin-si (KR); Byeong Jae AHN, Yongin-si (KR); Jeong Hyun LEE, Yongin-si (KR)

(73) Assignee: Samsung Display Co., LTD., Yongin-si (KR)

(21) Appl. No.: 17/954,681

(22) Filed: Sep. 28, 2022

(30) Foreign Application Priority Data
Dec. 20, 2021 (KR) 10-2021-0183078

(51) Int. Cl. H01L 27/32; H01L 33/50; H01L 51/56; H01L 51/52; H01L 33/58

(52) U.S. Cl. CPC H01L 27/322; H01L 33/58; H01L 33/505; H01L 51/56; H01L 51/5268; H01L 25/167

(57) ABSTRACT

A display device includes including emission areas, a non-emission area. Light emitting elements are disposed on a substrate in the emission areas. A bank is disposed on the substrate in the non-emission area of the substrate and includes openings corresponding to the emission areas. Color conversion patterns are disposed in the openings of the bank and converts a wavelength band of light incident from the light emitting elements to emit light. Organic patterns are disposed on the color conversion patterns and are separated from each other. Color filters are disposed on the organic patterns. The color filters are sequentially stacked in a space between the organic patterns in the non-emission area.

### CROSS-REFERENCE TO RELATED APPLICATION

This application claims priority to and benefits of Korean Patent Application No. 10-2021-0183078 under 35 U.S.C. §119, filed in the Korean Intellectual Property Office (KIPO) on Dec. 20, 2021, the entire contents of which are incorporated herein by reference.

### BACKGROUND

### 1. Technical Field

The disclosure relates to a display device capable of improving light efficiency, and a method of manufacturing the display device.

### 2. Description of the Related Art

In recent years, as interest in information display is increasing, research and development for a display device are continuously being conducted.

### SUMMARY

Embodiments provide a display device capable of improving light efficiency.

Embodiments also provide a method of manufacturing the display device.

However, embodiments of the disclosure are not limited to those set forth herein. The above and other embodiments will become more apparent to one of ordinary skill in the art to which the disclosure pertains by referencing the detailed description of the disclosure given below.

In order to achieve an object of the disclosure, according to embodiments of the disclosure, a display device includes emission areas, a non-emission area, light emitting elements disposed on a substrate in the emission areas, a bank disposed on the substrate in the non-emission area and including openings corresponding to the emission areas, color conversion patterns disposed in the openings of the bank and converting a wavelength band of light incident from the light emitting elements to emit light, organic patterns disposed on the color conversion patterns and separated from each other, and color filters disposed on the organic patterns. The color filters are sequentially stacked in a space between the organic patterns in the non-emission area.

The color filters sequentially stacked in the non-emission area may form a light blocking structure.

The light blocking structure may be disposed directly on the bank and contact the bank.

A height of an upper surface of the light blocking structure and a height of an upper surface of the color filters in the emission areas with respect to the substrate may be substantially equal to each other.

The display device may further include inorganic patterns disposed between the color conversion patterns and the organic patterns in the emission areas.

A refractive index of the inorganic patterns may be less than a refractive index of the color conversion patterns.

The inorganic patterns may be spaced apart from each other and may be disposed in the emission areas.

The display device may further include a second capping layer disposed between the inorganic patterns and the organic patterns in the emission areas, and a first capping layer disposed between the color conversion patterns and the inorganic patterns.

Each of the first capping layer and the second capping layer may include patterns spaced apart from each other to correspond to the emission areas.

An average thickness of the organic patterns may be greater than half a thickness of one of the color filters and less than or substantially equal to a thickness of two of the color filters.

The display device may further include an overcoat layer disposed on the color filters and overlapping the color filters in a plan view.

The display device may further include an upper substrate disposed on the color filters, and a filler disposed between the color filters and the upper substrate.

The light emitting elements may include inorganic light emitting diodes.

The light emitting elements may include organic light emitting diodes.

In order to achieve an object of the disclosure, according to embodiments of the disclosure, a display device includes an emission area, a non-emission area surrounding the emission area, a light emitting element disposed on a substrate in the emission area, a bank disposed on the substrate in the non-emission areas and including an opening corresponding to the emission area, a color conversion pattern disposed in the opening of the bank and converting a wavelength band of light incident from the light emitting element to emit light, color filters sequentially stacked on the bank, and an organic pattern disposed between one of the color filters and the color conversion pattern in the emission area. An uppermost surface of the color filters is substantially flat in the emission area and the non-emission area.

The organic pattern may be disposed in an island shape in the emission area by the color filters.

The color filters may be formed directly on the bank in the non-emission area, and one of the color filters may contact the bank.

The display device may further include an inorganic pattern disposed between the color conversion pattern and the organic pattern in the emission area.

In order to achieve an object of the disclosure, according to embodiments of the disclosure, a method of manufacturing a display device includes preparing a panel including light emitting elements disposed in emission areas and a bank disposed on a substrate in a non-emission area and having openings corresponding to the emission areas, forming color conversion patterns converting a wavelength band of light incident from the light emitting elements to emit light, in the openings of the bank, forming an organic layer on the color conversion patterns, forming organic patterns by etching a portion of the organic layer overlapping the non-emission area, and forming color filters on the bank and the organic patterns. The color filters are filled in a form in which the color filters are sequentially stacked in a space between the organic patterns in the non-emission area.

The forming of the organic layer may include forming at least one inorganic layer on the color conversion patterns, and forming the organic layer on the at least one inorganic layer. The forming of the organic patterns may include etching the at least one inorganic layer to form inorganic patterns from the at least one inorganic layer.

In the display device and the method of manufacturing the display device according to embodiments of the disclosure, the organic patterns may be disposed on the color conversion patterns in the emission area. The color filter may be disposed to cover the organic patterns and may be filled in a space between the organic patterns to form a light blocking structure. An upper surface of the color filter may be flat in the emission area and the non-emission area. Therefore, scattering (or surface scattering) of light due to a step difference of the color filter occurring between the emission area and the non-emitting area may be controlled, and light efficiency of a sub-pixel may be improved.

Since the organic pattern is disposed in the island shape for each sub-pixel and the organic pattern is covered by the color filter (or the light blocking structure), light loss (e.g., light loss generated due to light generated in sub-pixel and proceeding to adjacent sub-pixel) may be improved (e.g., decreased or prevented).

An effect according to an embodiment of the disclosure is not limited by the contents exemplified above, and more various effects are included in the specification.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a plan view schematically illustrating a display device according to embodiments of the disclosure;

FIG. 2 is a cross-sectional view schematically illustrating the display device of FIG. 1;

FIG. 3 is a schematic cross-sectional view illustrating an embodiment of the display device of FIG. 1;

FIG. 4 is a schematic cross-sectional view of a sub-pixel included in the display device of FIG. 3;

FIG. 5 is a schematic plan view illustrating an example of an organic pattern included in the display device of FIG. 3;

FIG. 6 is a schematic cross-sectional view illustrating a display device according to a comparative example;

FIG. 7 is a schematic diagram illustrating color filters included in the display device according to the comparative example of FIG. 6 and light displayed therethrough;

FIG. 8 is a schematic cross-sectional view illustrating another embodiment of the display device of FIG. 1;

FIG. 9 is a schematic cross-sectional view illustrating an example of a display element layer and a pixel circuit layer included in the display device of FIG. 2;

FIG. 10 is a schematic cross-sectional view illustrating another example of the display element layer and the pixel circuit layer included in the display device of FIG. 2; and

FIGS. 11A to 11I are schematic diagrams illustrating a method of manufacturing the display device of FIG. 3.

### DETAILED DESCRIPTION OF THE EMBODIMENT

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing exemplary features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Also, like reference numerals denote like elements. Further, in the accompanying drawings, the size and relative sizes of the elements may be exaggerated for clarity and/or descriptive purposes. When an embodiment may be implemented differently, a specific process order may be performed differently from the described order. For example, two consecutively described process order may be performed differently from the described order.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms(or meanings) as well, unless the context clearly dictates otherwise.

It should be understood that, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

In addition, a case where a portion of a layer, a layer, an area, a plate, or the like is referred to as being “on” another portion, it includes not only a case where the portion is “directly on” another portion, but also a case where there is further another portion between the portion and another portion. In addition, in the specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and another portion.

In the application, in a case where “a component (for example, ‘a first component’) is operatively or communicatively coupled with/to or “connected to” another component (for example, ‘a second component’), the case should be understood that the component may be directly connected to the other component, or may be connected to the other component through another component (for example, a ‘third component’). In contrast, in a case where a component (for example, ‘a first component’) is “directly coupled with/to or “directly connected” to another component (for example, ‘a second component’), the case may be understood that another component (for example, ‘a third component’) is not present between the component and the other component.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

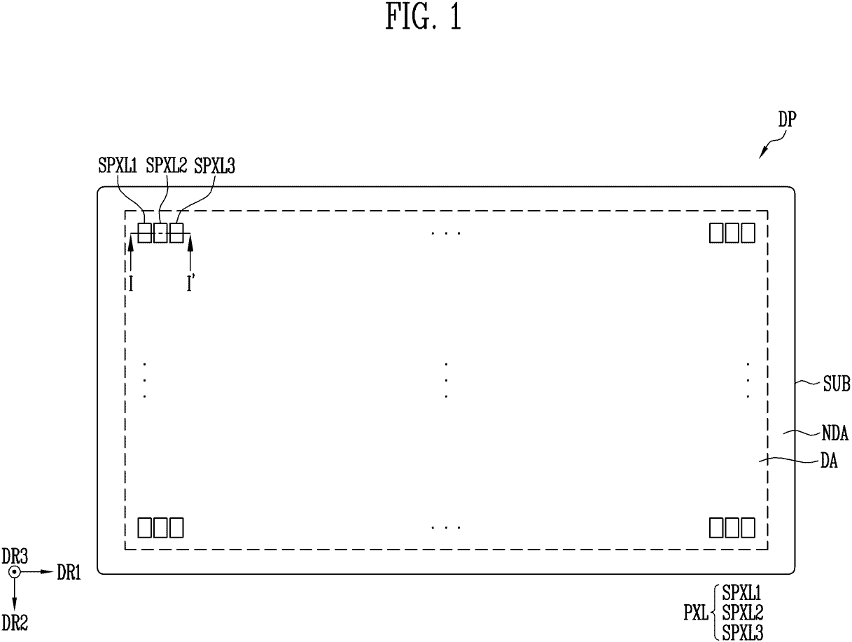

FIG. 1 is a plan view schematically illustrating a display device according to embodiments of the disclosure. For convenience, in FIG. 1, a structure of the display panel DP is briefly shown based on a display area DA. However, according to an embodiment, at least one driving circuit part, lines, and/or pads, which are/is not shown, may be further provided on the display panel DP.

Referring to FIG. 1, the display device may include the display panel DP. A display surface may be applied to at least one surface of the display device, such as a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, an automotive (or a vehicle display), a transparent display, or a wearable device (e.g., glass glasses, and a smart watch), and the disclosure may be applied to the display device.

The display panel DP may have various shapes. For example, the display panel DP may be provided in a rectangular plate shape, but is not limited thereto. For example, the display panel DP may have a circular shape, an elliptical shape, or the like. The display panel DP may include an angled corner and/or a curved corner. For convenience of description, in FIG. 1, the display panel DP may have a rectangular shape having a pair of long sides and a pair of short sides. An extension direction of the long side may be indicated as a first direction DR1, and an extension direction of the short side may be indicated as a second direction DR2. A direction perpendicular to the extension directions of the long side and the short side may be indicated as a third direction DR3.

The display panel DP may display an image. As the display panel DP, a display panel capable of self-luminescence such as an inorganic light emitting display panel using an inorganic light emitting diode as a light emitting element, an ultra-small light emitting diode display panel (a micro-scale LED display panel or a nano-scale LED display panel) using a small light emitting diode as small as a micrometer-scale (or nanometer-scale) as a light emitting element, and a quantum dot light emitting display panel (QD LED panel) using a quantum dot and an inorganic light emitting diode may be used. As the display panel DP, a non-luminous display panel such as an organic light emitting display panel (OLED panel) using an organic light emitting diode as a light emitting element, a liquid crystal display panel (LCD panel), an electrophoretic display panel (EPD panel), and an electro-wetting display panel (EWD panel) may be used. However, the disclosure is not limited thereto, and the display panel DP may include various panels.

The display panel DP and a substrate SUB for forming the display panel DP may include a display area DA for displaying an image and a non-display area NDA except for the display area DA. The display area DA may configure a screen on which the image is displayed, and the non-display area NDA may be a remaining area except for the display area DA. According to an embodiment, a shape of the display area DA and a shape of the non-display area NDA may be relatively designed.

Pixels PXL may be disposed in the display area DA on the substrate SUB. For example, the display area DA may include pixel parts (or pixel areas) in which each pixel PXL is disposed.

The non-display area NDA may be disposed around the display area DA. Various lines, pads, and/or built-in circuits electrically connected to the pixels PXL of the display area DA may be disposed in the non-display area NDA.

The display panel DP may include the substrate SUB (or a base layer) and the pixels PXL. The pixels PXL may be provided or disposed on the substrate SUB.

The substrate SUB may be formed of an insulating material such as glass or resin. The substrate SUB may be formed of a material having flexibility to be bent or folded. The substrate SUB may have a single layer structure or a multilayer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the material configuring the substrate SUB is not limited to the above-described embodiments.

The pixels PXL may be arranged along a row extending in the first direction DR1 and a column extending in the second direction DR2 intersecting (or crossing) the first direction DR1. For example, the pixels PXL may be arranged according to a stripe or PENTILE™ arrangement structure or the like. However, the disclosure is not limited thereto, and various known embodiments may be applied.

In an embodiment, the pixel PXL may include a first sub-pixel SPXL1, a second sub-pixel SPXL2, and a third sub-pixel SPXL3.

For example, each of the first sub-pixel SPXL1, the second sub-pixel SPXL2, and the third sub-pixel SPXL3 may emit light of a color. For example, the first sub-pixel SPXL1 may emit light of a first color (e.g., red), the second sub-pixel SPXL2 may emit light of a second color (e.g., green), and the third sub-pixel SPXL3 may emit light of a third color (e.g., blue). However, the color, type, number, and/or the like of the first sub-pixel SPXL1, the second sub-pixel SPXL2, and the third sub-pixel SPXL3 configuring each pixel PXL are/is not limited to a specific example. In the drawing, the first sub-pixel SPXL1, the second sub-pixel SPXL2, and the third sub-pixel SPXL3 may have a rectangular shape, but the disclosure is not limited thereto, and the first sub-pixel SPXL1, the second sub-pixel SPXL2, and the third sub-pixel SPXL3 may be modified into various shapes. The first sub-pixel SPXL1, the second sub-pixel SPXL2, and the third sub-pixel SPXL3 may be provided to have different areas (or sizes).

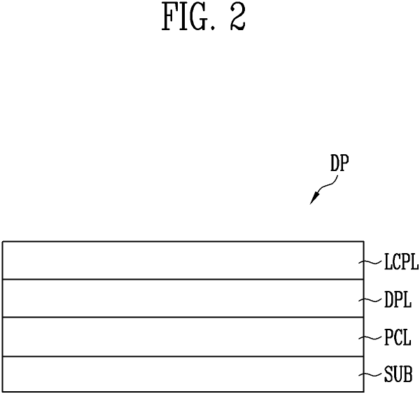

FIG. 2 is a cross-sectional view schematically illustrating the display device of FIG. 1.

Referring to FIGS. 1 and 2, the display panel DP may include a pixel circuit layer PCL, a display element layer DPL, and a light conversion pattern layer LCPL sequentially disposed on the substrate SUB.

The pixel circuit layer PCL may be provided on the substrate SUB and may include transistors and signal lines electrically connected to the transistors. For example, each transistor may have a form in which a semiconductor layer, a gate electrode, and a source/drain electrode are sequentially stacked with an insulating layer interposed therebetween. The semiconductor layer may include at least one of amorphous silicon, poly silicon, low temperature poly silicon, an oxide semiconductor, and an organic semiconductor. The gate electrode and the source/drain electrode may include at least one of aluminum (Al), copper (Cu), titanium (Ti), and molybdenum (Mo), but the disclosure is not limited thereto. The pixel circuit layer PCL may include one or more insulating layers.

The display element layer DPL may be disposed on the pixel circuit layer PCL. The display element layer DPL may include a light emitting element emitting light. The light emitting element may be, for example, an inorganic light emitting element including an inorganic light emitting material. However, the light emitting element is not limited thereto, and for example, the light emitting element may be an organic light emitting diode.

According to an embodiment, a thin layer encapsulation layer may be selectively disposed on the display element layer DPL. The thin layer encapsulation layer may be an encapsulation substrate or may have a form of an encapsulation layer formed of multiple layers. In case that the thin layer encapsulation layer has the form of the encapsulation layer, the thin layer encapsulation layer may include an inorganic layer and/or an organic layer. For example, the thin layer encapsulation layer may have a form in which an inorganic layer, an organic layer, and an inorganic layer are sequentially stacked. The thin layer encapsulation layer may prevent external air and moisture from penetrating into the display element layer DPL and the pixel circuit layer PCL.

The light conversion pattern layer LCPL may be disposed on the display element layer DPL. The light conversion pattern layer LCPL may change a wavelength (or color) of light emitted from the display element layer DPL by using a quantum dot. The light conversion pattern layer LCPL may selectively transmit light of a wavelength (or color) by using a color filter. The light conversion pattern layer LCPL may be formed on a base surface provided by the display element layer DPL through a successive process.

The light conversion pattern layer LCPL may be provided separately from the display element layer DPL, but the disclosure is not limited thereto. For example, the light emitting element provided in the display element layer DPL may be implemented as a light emitting element (e.g., quantum dot display element) that changes the wavelength of light emitted using a quantum dot.

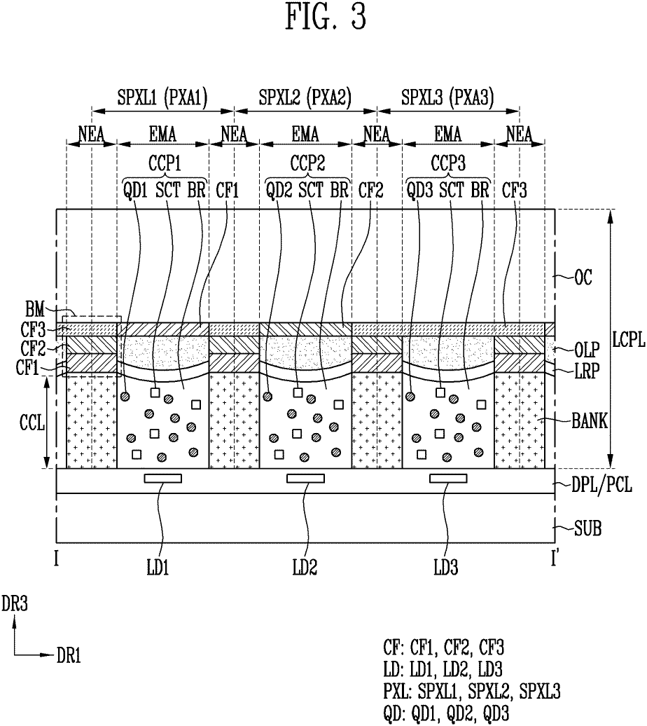

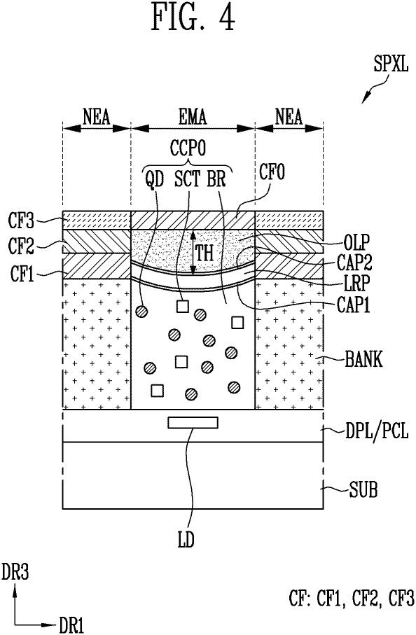

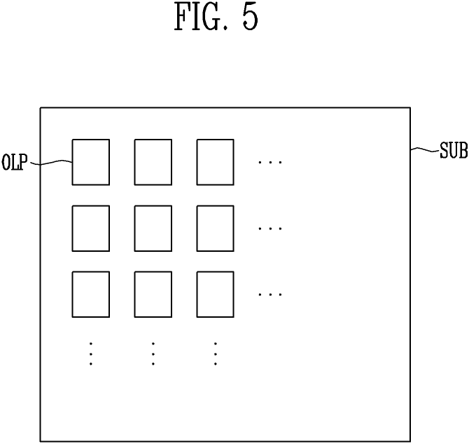

FIG. 3 is a schematic cross-sectional view illustrating an embodiment of the display device of FIG. 1. FIG. 3 schematically shows the pixel PXL taken along line I-I′ of FIG. 1. FIG. 4 is a schematic cross-sectional view of a sub-pixel included in the display device of FIG. 3. The first, second, and third sub-pixels SPX1, SPXL2, and SPXL3 of FIG. 3 are substantially the same as each other, and a sub-pixel SPXL corresponding to one of the first, second, and third sub-pixels SPX1, SPXL2, and SPXL3 of FIG. 3 is shown in FIG. 4. FIG. 5 is a schematic plan view illustrating an example of an organic pattern included in the display device of FIG. 3.

Referring to FIGS. 1 to 4, the first sub-pixel SPXL1, the second sub-pixel SPXL2, and the third sub-pixel SPXL3 may be disposed on the substrate SUB.

In an embodiment of the disclosure, unless otherwise specified, “formed and/or provided on a same layer” may mean formed in a same process (or by a same process), and “formed and/or provided on different layers” may mean formed in different processes.

The pixel circuit layer PCL and the display element layer DPL may be disposed on the substrate SUB. For convenience of description, the pixel circuit layer PCL is shown together with the display element layer DPL, but as described with reference to FIG. 2, the pixel circuit layer PCL may be disposed between the substrate SUB and the display element layer DPL.

The display element layer DPL may include a light emitting element LD provided in each emission area EMA. For example, a first light emitting element LD1 may be provided in a first pixel part PXA1, a second light emitting element LD2 may be provided in a second pixel part PXA2, and a third light emitting element LD3 may be provided in a third pixel part PXA3.

The light emitting element LD may be formed of an organic light emitting diode, or an inorganic light emitting diode such as a micro light emitting diode or a quantum dot light emitting diode. In an embodiment, the light emitting element LD may be an ultra-small light emitting diode, for example, having a size as small as a nanometer-scale to a micrometer-scale, using a material of an inorganic crystal structure. The light emitting elements LD may be electrically connected to each other in parallel and/or in series with another light emitting element LD disposed adjacent to each other in each sub-pixel, but the disclosure is not limited thereto. The light emitting element LD may configure a light source of each sub-pixel. For example, each sub-pixel PXL may include at least one light emitting element LD driven by a signal (e.g., a scan signal and a data signal) and/or power (e.g., first driving power and second driving power).

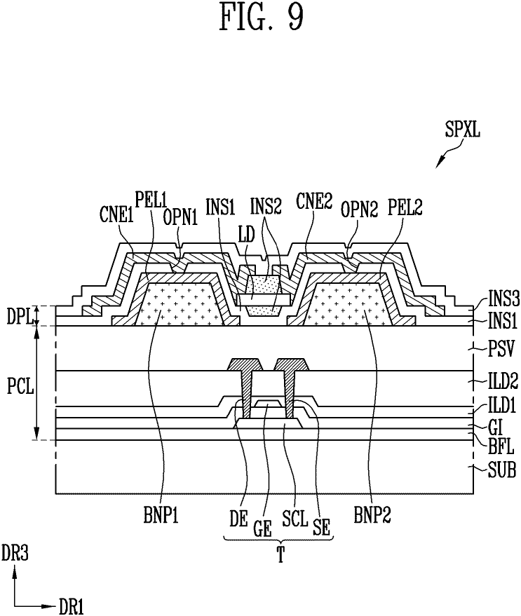

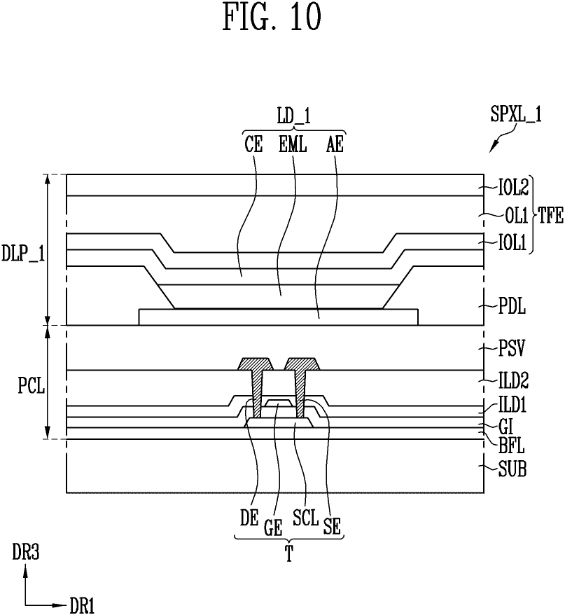

A detailed configuration of the pixel circuit layer PCL and the display element layer DPL is described below with reference to FIGS. 9 and 10.

The light conversion pattern layer LCPL may include a color conversion layer CCL, a color filter CF (or color filter layer), and an overcoat layer OC. The light conversion pattern layer LCPL may include a low refractive pattern LRP and an organic pattern OLP (or planarization pattern) formed between the color conversion layer CCL and the color filter CF (or between a corresponding color conversion pattern CCP0 and a corresponding color filter CF0) in the emission area EMA.

The color conversion layer CCL may include a bank BANK and first, second, and third color conversion patterns CCP1, CCP2, and CCP3 (or first, second, and third color conversion layers).

The bank BANK may be disposed on the display element layer DPL.

The bank BANK may be positioned in a non-emission area NEA of the first, second, and third sub-pixels SPXL1, SPXL2, and SPXL3. The bank BANK may be formed between the first, second, and third sub-pixels SPXL1, SPXL2, and SPXL3 to surround each emission areas EMA. For example, the bank BANK may be formed between adjacent ones of the first, second, and third sub-pixels SPXL1, SPXL2, and SPXL3. The bank BANK may define the emission area EMA of each of the first, second, and third sub-pixels SPXL1, SPXL2, and SPXL3. The bank BANK may prevent a solution for forming the first, second, and third color conversion patterns CCP1, CCP2, and CCP3 in the emission area EMA from flowing into the emission area EMA of an adjacent pixel, or may function as a dam structure that controls an amount (e.g., a predetermined or selected amount) of solution to be supplied to each emission area EMA.

The bank BANK may include an organic material or an inorganic material. In an embodiment, the bank BANK may include a black matrix material (or light blocking material). The bank BANK may prevent light generated from the sub-pixel SPXL (e.g., the first sub-pixel SPXL1) from proceeding to an adjacent sub-pixel (e.g., the second sub-pixel SPXL2 and the third sub-pixel SPXL3).

A thickness (or maximum thickness) of the bank BANK may be within a range of about 4 µm to about 20 µm. For example, the thickness of the bank BANK may be about 10 µm.

An opening for exposing the display element layer DPL may be formed in the bank BANK to correspond to the emission area EMA.

The first, second, and third color conversion patterns CCP1, CCP2, and CCP3 may be disposed in each opening of the bank BANK.

The first, second, and third color conversion patterns CCP1, CCP2, and CCP3 may include a base resin BR, color conversion particles QD, and light scattering particles SCT.

The base resin BR may have high light transmittance and an excellent dispersion characteristic for the color conversion particles QD. For example, the base resin BR may include at least one organic material such as an epoxy resin, an acrylates resin, a cardo resin, and an imide resin.

The color conversion particles QD may convert light of a color (or wavelength band) emitted from the light emitting element LD disposed in a pixel into light of a specific color. For example, in case that the first sub-pixel SPXL1 is a red pixel, the first color conversion pattern CCP1 may include first color conversion particles QD1 of a red quantum dot converting light emitted from the first light emitting element LD1 into light of a red (or red wavelength band). As another example, in case that the second sub-pixel SPXL2 is a green pixel, the second color conversion pattern CCP2 may include second color conversion particles QD2 of a green quantum dot converting light emitted from the second light emitting element LD2 into light of a green (or green wavelength band). As still another example, in case that the third sub-pixel PXL3 is a blue pixel, the third color conversion pattern CCP3 may include third color conversion particles QD3 of a blue quantum dot converting light emitted from the third light emitting element LD3 into light of a blue (or blue wavelength band). In other embodiments, in case that the third light emitting element LD3 emits blue light, the third color conversion pattern CCP3 may not include the third color conversion particles QD3.

The color conversion particles QD may have a spherical shape, a pyramidal shape, a multi-arm shape, a cubic shape, or the like. The color conversion particles QD may include at least one of nanoparticles, nanotubes, nanowires, nanofiber, nanoplatelet particles, and the like, but the disclosure is not limited thereto, and the shape of the color conversion particles QD may be variously changed.

In an embodiment, blue light having a relatively short wavelength in a visible light area (or range) may be incident on the first and second color conversion particles QD1 and QD2, and an absorption coefficient of the first and second color conversion particles QD1 and QD2 may be increased. Accordingly, efficiency of light emitted from the first sub-pixel SPXL1 and the second sub-pixel SPXL2 may be increased (e.g., finally increased), and excellent color reproducibility may be secured. Each pixel of the first, second, and third sub-pixels SPXL1, SPXL2, and SPXL3 may be configured using the light emitting element LD of a same color (e.g., a blue light emitting element), and manufacturing efficiency of the display device may be increased.

The light scattering particles SCT may have a refractive index different from that of the base resin BR and form an optical interface with the base resin BR. The light scattering particles SCT may be metal oxide particles or organic particles. According to an embodiment, the light scattering particles SCT may be omitted.

The low refractive pattern LRP may be disposed on the color conversion layer CCL in the emission area EMA. In other embodiments, the lower refractive pattern LRP may be disposed on the corresponding color conversion pattern CCP0 of FIG. 4 in the emission area EMA.

The low refractive pattern LRP may recycle the light provided from the color conversion layer CCL by total reflection to improve light efficiency (e.g., external quantum efficiency or light output efficiency). Thus, the low refractive pattern LRP may have a relatively low refractive index compared to the color conversion layer CCL (and organic pattern OLP).

In an embodiment, the low refractive pattern LRP may include an organic material and/or an inorganic material. For example, the low refractive pattern LRP may include a base resin and a hollow particle (or hollow particles) dispersed in the base resin. The hollow particle may include a hollow silica particle. The hollow particle may be a pore formed by porogen, but is not limited thereto. The low refractive pattern LRP may include at least one of a zinc oxide (ZnO) particle, a titanium dioxide (TiO₂) particle, and a nano silicate particle, but is not limited thereto.

The low refractive pattern LRP may be disposed in an island shape for each sub-pixel SPXL. The low refractive pattern LRP may be disposed in an island shape for each emission area EMA of the sub-pixel SPXL. For example, the low refractive patterns LRP of the first, second, and third sub-pixels SPX1, SPXL2, and SPXL3 may be separated from each other. For example, the low refractive pattern LRP may be disposed (e.g., entirely disposed) on the substrate SUB to cover the color conversion layer CCL. The low refractive pattern LRP may cover (or overlap, e.g., in a plan view) the bank BANK and first, second, and third color conversion patterns CCP1, CCP2, and CCP3, and thereafter, the low refractive pattern LRP may be patterned to be disposed only in the emission area EMA through an etching process or the like.

In an embodiment, in the emission area EMA, a first capping layer CAP1 (or first capping pattern) may be disposed between the corresponding color conversion pattern CCP0 and the low refractive pattern LRP, and a second capping layer CAP2 (or second capping pattern) may be disposed between the low refractive pattern LRP and the corresponding color filter CF0.

As shown in FIG. 4, the first capping layer CAP1 may seal (or cover) the corresponding color conversion pattern CCP0. The first capping layer CAP1 may be provided in the emission area EMA of each sub-pixel SPXL. The first capping layers CAP1 (or first capping patterns) of the first, second, and third sub-pixels SPX1, SPXL2, and SPXL3 may be spaced apart or separated from each other in a part of the sub-pixels SPXL. However, the disclosure is not limited thereto, and the first capping layer CAP1 may be provided over the first, second, and third sub-pixels SPX1, SPXL2, and SPXL3. The first capping layer CAP1 may prevent an impurity (or a solution used in a subsequent process) such as moisture or air from penetrating from the outside and damaging or contaminating the color conversion layer CCL. For example, the first capping layer CAP1 may protect the color conversion layer CCL from the impurity such as the moisture of the air provided from the outside.

In an embodiment, the first capping layer CAP1 may include an insulating material of at least one of silicon oxide (SiOₓ), silicon nitride (SiNₓ), silicon oxynitride (SiOₓN_{y}), aluminum oxide (AlOₓ), and titanium oxide (TiOₓ), and may be configured as a single layer or multiple layers, but is not limited thereto.

The second capping layer CAP2 may be disposed on the low refractive pattern LRP in the emission area EMA. The second capping layer CAP2 may be disposed between the low refractive pattern LRP and the corresponding color filter CF0 in the emission area EMA. The second capping layers CAP2 (or second capping patterns) of the first, second, and third sub-pixels SPX1, SPXL2, and SPXL3 may be spaced apart or separated from each other in the part of the sub-pixels SPXL. The second capping layer CAP2 may prevent an impurity such as moisture or air from penetrating from the outside and damaging or contaminating the low refractive pattern LRP. For example, the second capping layer CAP2 may protect the low refractive pattern LRP from the impurity such as the moisture or air, which is provided from the outside.

In an embodiment, the second capping layer CAP2 may include an insulating material of at least one of silicon oxide (SiOₓ), silicon nitride (SiNₓ), silicon oxynitride (SiOₓN_{y}), aluminum oxide (AlOₓ), and titanium oxide (TiOₓ), and may be configured as a single layer or multiple layers, but is not limited thereto.

The organic pattern OLP may be disposed on the low refractive pattern LRP (or second capping layer CAP2) in the emission area EMA, and may provide a flat surface thereon.

The organic pattern OLP may include at least one organic material such as acrylates resin, epoxy resin, phenolic resin, polyamides resin, polyimides resin, polyester resin, polyphenylenesulfides resin, and benzocyclobutene (BCB), but is not limited thereto.

The organic pattern OLP may be disposed in an island shape for each sub-pixel SPXL (or for each emission area EMA of the sub-pixel SPXL). As shown in FIG. 5, the organic patterns OLP may be separated from each other. For example, the organic pattern OLP may be disposed entirely on the substrate SUB to cover a low refractive layer corresponding to the low refractive pattern LRP. The organic pattern OLP may be patterned to be disposed only in the emission area EMA through an etching process or the like. The low refractive layer may be patterned after or simultaneously with the patterning of the organic pattern OLP to form the low refractive pattern LRP.

For reference (or comparison), in case that an organic layer (or a planarization layer) corresponding to the organic pattern OLP and/or a low refractive layer corresponding to the low refractive pattern LRP are/is disposed entirely on the substrate SUB, some of light emitted from the corresponding color conversion pattern CCP0 of the sub-pixel SPXL may proceed in the first direction DR1 through the organic layer and/or the low refractive layer, and light loss may occur in the sub-pixel SPXL. The light loss of the sub-pixel SPXL may be improved by disposing the organic pattern OLP and the low refractive pattern LRP in an island shape for each sub-pixel SPXL (and by disposing a light blocking structure BM between adjacent organic patterns OLP).

The color filter CF may be disposed on the organic pattern OLP and the bank BANK.

The color filter CF may include a color filter material that selectively transmits the light of the color converted by the color conversion layer CCL. The color filter CF may include a red color filter, a green color filter, and a blue color filter. For example, in case that the first sub-pixel SPXL1 is a red pixel, a first color filter CF1 that transmits red light may be disposed on the first sub-pixel SPXL1. In case that the second sub-pixel SPXL2 is a green pixel, a second color filter CF2 that transmits green light may be disposed on the second sub-pixel SPXL2. In case that the third sub-pixel PXL3 is a blue pixel, a third color filter CF3 that transmits blue light may be disposed on the third sub-pixel PXL3.

In an embodiment, the first, second, and third color filters CF1, CF2, and CF3 may be disposed to overlap each other in the non-emission area NEA. The first, second, and third color filters CF1, CF2, and CF3 may be filled in a form in which the first, second, and third color filters CF1, CF2, and CF3 are sequentially stacked in a space (or valley) between the organic patterns OLP. The first, second, and third color filters CF1, CF2, and CF3 may cover the organic pattern OLP. For example, the first color filter CF1, the second color filter CF2, and the third color filter CF3 may be sequentially stacked in the space between the organic patterns OLP. According to an embodiment, a stack order of the first, second, and third color filters CF1, CF2, and CF3 may be changed.

The first, second, and third color filters CF1, CF2, and CF3 may be sequentially stacked in the non-emission area NEA, and form the light blocking structure BM (or light blocking pattern). The light blocking structure BM may prevent light generated in the sub-pixel SPXL (e.g., the second sub-pixel SPXL2) from proceeding to the adjacent sub-pixel (e.g., the first sub-pixel SPXL1 and the third sub-pixel SPXL3) through the low refractive pattern LRP and the organic pattern OLP.

In case that the bank BANK is exposed in the non-emission area NEA by the low refractive pattern LRP and the organic pattern OLP, the light blocking structure BM (e.g., first, second, and third color filters CF1, CF2, and CF3) may be disposed (e.g., directly disposed) on the bank BANK and may be in contact with the bank BANK. For example, the first color filter CF1 may be in contact with the bank BANK.

In an embodiment, a height (e.g., a height in the third direction DR3) of an upper surface of the light blocking structure BM may be substantially the same as a height (or average height) of an upper surface of the corresponding color filter CF0 in the emission area EMA, based on (or from) the substrate SUB (or an upper surface of the substrate SUB). For example, the uppermost surface of the color filter CF may be substantially flat in the emission area EMA and the non-emission area NEA.

Thus, a thickness TH (or average thickness) of each of the organic patterns OLP may be greater than half a thickness of one of the first, second, and third color filters CF1, CF2 and CF3, and may be less than a thickness of two of the first, second, and third color filters CF1, CF2, and CF3. The thickness may be a thickness, a height, or a width in the third direction DR3.

For example, a thickness of the first color filter CF1 may be about 4.2 µm, a thickness of the second color filter CF2 may be about 3.2 µm, and a thickness of the third color filter CF3 may be about 3.0 µm. The light blocking structure BM may have a thickness (or height) of about 10 µm. In case that a thickness of the low refractive pattern LRP is in a range of about 2 to about 3 µm and a thickness of the corresponding color filter CF0 is in a range of about 3.0 µm to about 4.2 µm, a thickness of the organic pattern OLP may be in a range of about 3 µm to about 5 µm.

A deviation may exist in a height of an upper surface of the corresponding color filter CF0 for each sub-pixel SPXL due to a thickness difference between the first, second, and third color filters CF1, CF2, and CF3. However, the deviation may be a level of about ±5% based on an upper surface of the light blocking structure BM. Therefore, the uppermost surface of the color filter CF may be substantially flat in the emission area EMA and the non-emission area NEA.

For reference, in case that a step difference (or height difference) exists between the upper surface of the light blocking structure BM (e.g., the first, second, and third color filters CF1, CF2, and CF3 sequentially stacked in non-emission area NEA) and the upper surface of the corresponding color filter CF0 (e.g., the color filter disposed in the emission area EMA), light scattering (e.g., surface scattering, or diffuse reflection) may occur differently for each sub-pixel SPXL due to the step difference, and the scattered light may affect light emitted from the sub-pixel SPXL. Since the uppermost surface of the color filter CF is substantially flat in the emission area EMA and the non-emission area NEA, the light scattering may be controlled, and the sub-pixel SPXL may accurately emit light of a desired color.

Meanwhile, instead of forming the light blocking structure BM, the bank BANK may be thickly formed up to the height of the upper surface of the color filter CF, but an upper end portion of the bank BANK (e.g., the bank BANK thickened by about 10 µm) may not be cured due to a decrease of light transmittance. For example, the bank BANK may not be formed normally. In another example, the bank BANK may be formed double, but a manufacturing process for the double formation of the bank BANK may be complicated or manufacturing cost may be increased. In the embodiments of FIGS. 3 and 4, only the organic pattern OLP may be formed by etching the organic layer (or planarization layer) disposed under the color filter CF to substantially planarize the uppermost surface of the color filter CF in the emission area EMA and the non-emission area NEA. For example, during an etching process performed to form a pad in the non-display area NDA shown in FIG. 1, the organic pattern OLP may be formed. For example, light efficiency may be improved without changing a manufacturing process and/or increasing manufacturing cost.

The overcoat layer OC may be disposed on the color filter CF. The overcoat layer OC may be provided over the first, second, and third sub-pixels SPXL1, SPXL2, and SPXL3. The overcoat layer OC may cover a lower member including the color filter CF. The overcoat layer OC may prevent moisture or air from penetrating into the above-described lower member. The overcoat layer OC may protect the above-described lower member from a foreign substance such as dust.

In an embodiment, the overcoat layer OC may be configured as a single layer or multiple layers including at least one organic layer and inorganic layer. For example, the overcoat layer OC may be configured as multiple layers including at least one inorganic layer disposed on the color filter CF and at least one organic layer stacked on the inorganic layer. The overcoat layer OC may selectively further include at least one inorganic layer disposed on the organic layer. However, a structure of the overcoat layer OC is not limited thereto. For example, in another embodiment, the overcoat layer OC may be configured of only inorganic layers of multiple layers. For example, a configuration material and/or a structure of the overcoat layer OC may be variously changed according to an embodiment.

In an embodiment, the overcoat layer OC may include at least one organic material such as acrylates resin, epoxy resin, phenolic resin, polyamides resin, polyimides resin, polyester resin, polyphenylenesulfides resin, and benzocyclobutene (BCB), but is not limited thereto. However, the disclosure is not limited thereto, and the overcoat layer OC may include at least one inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

As described above, since the color filter CF is filled in the space between the organic patterns OLP formed in the emission area EMA to form the light blocking structure BM, the upper surface of the color filter CF may be flat in the emission area EMA and the non-emission area NEA. For example, the light blocking structure BM may not protrude than the corresponding color filter CF0 of the emission area EMA. Therefore, the light scattering (or surface scattering) due to the step difference between the light blocking structure BM and the corresponding color filter CF0 may be controlled, and the sub-pixel SPXL may accurately emit light of a color.

Since the organic pattern OLP and the low refractive pattern LRP are disposed in the island shape for each sub-pixel SPXL, light loss may be improved (e.g., decreased or prevented). For example, light loss generated due to light generated in the sub-pixel SPXL and proceeding to an adjacent sub-pixel may be improved (e.g., decreased or prevented).

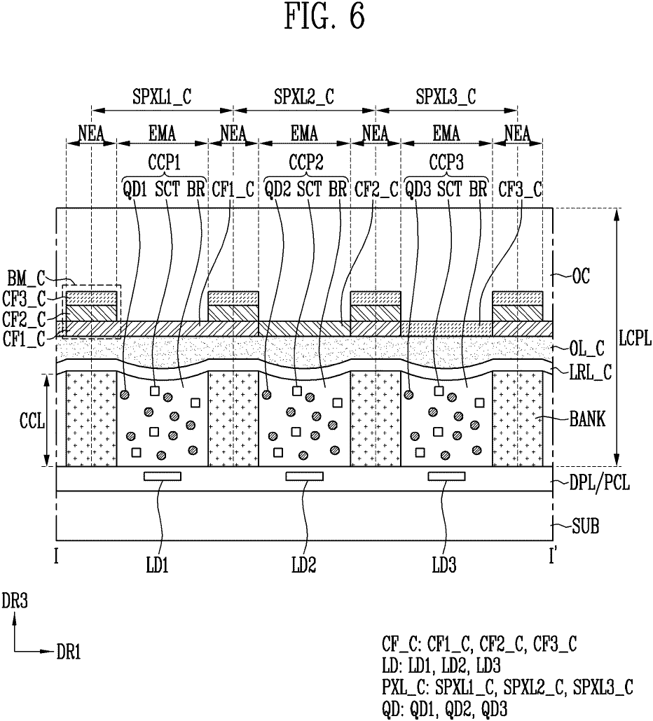

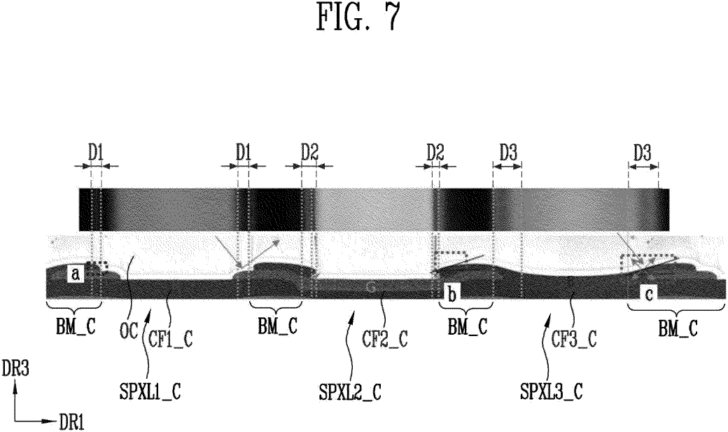

FIG. 6 is a schematic cross-sectional view illustrating a display device according to a comparative example. FIG. 6 shows a cross-sectional view corresponding to FIG. 3. FIG. 7 is a schematic diagram illustrating color filters included in the display device according to the comparative example of FIG. 6 and light displayed therethrough.

Referring to FIGS. 3 and 6, the display device of FIG. 6 (or a pixel PXL_C) may be substantially the same as or similar to the display device (or pixel PXL) of FIG. 3 except for a low refractive layer LRL_C (or low refractive film), an organic layer OL_C (or organic film), and a light blocking structure BM_C. Therefore, a substantially identical or similar description is not repeated.

The low refractive layer LRL_C may be disposed on the color conversion layer CCL. The low refractive layer LRL_C may be disposed (e.g., entirely disposed) on the substrate SUB to cover the color conversion layer CCL. For example, the low refractive layer LRC_C may cover the bank BANK and the first, second, and third color conversion patterns CCP1, CCP2, and CCP3.

The organic layer OL_C may be disposed on the low refractive layer LRL_C and may provide a flat surface thereon. The organic layer OL_C may be disposed (e.g., entirely disposed) on the substrate SUB to cover the low refractive layer LRL_C.

Since the organic layer OL_C and the low refractive layer LRL_C are successively provided in the first direction DR1 over first, second, and third sub-pixels SPXL1_C, SPXL2_C, and SPXL3_C, some of light emitted from the second color conversion pattern CCP2 of the second sub-pixel SPXL2_C may proceed in the first direction DR1 through the low refractive layer LRL_C and the organic layer OL_C. For example, the some of the light emitted from the second color conversion pattern CCP2 of the second sub-pixel SPXL2_C may proceed toward the first sub-pixel SPXL1_C and/or the third sub-pixel SPXL3_C. For example, light loss of the second sub-pixel SPXL2_C may occur.

The organic pattern OLP and the low refractive pattern LRP of the display device (or pixel PXL) of FIG. 3 may be disposed in the island shape for each sub-pixel SPXL. The light blocking structure BM may be formed between the adjacent organic patterns OLP. Thus, the light loss may be improved (e.g., decreased or prevented).

The color filter CF_C may be disposed on the organic layer OL_C. The color filter CF_C may include first, second, and third color filters CF1_C, CF2_C, and CF3_C.

The first, second, and third color filters CF1_C, CF2_C, and CF3_C may be disposed to overlap each other in the non-emission area NEA. The first, second, and third color filters CF1_C, CF2_C, and CF3_C sequentially stacked in the non-emission area NEA may form the light blocking structure BM_C.

The light blocking structure BM_C may protrude in the third direction DR3 than the color filter CF_C disposed in the emission area EMA. For example, the light blocking structure BM_C may protrude in the third direction DR3 by at least about 6 µm than the color filter CF_C disposed in the emission area EMA.

As shown in FIG. 7, the light blocking structure BM_C (e.g., area ‘a’) positioned at an edge of the first sub-pixel SPXL1_C, the light blocking structure BM_C (e.g., area ‘b’) positioned at an edge of the second sub-pixel SPXL2_C, and the light blocking structure BM_C (e.g., area ‘c’) positioned at an edge of the third sub-pixel SPXL3_C may have different cross-sectional shapes from one another. For example, the third color filter CF_C may have a taper angle of about 28 degrees in area ‘a’, a taper angle of about 14 degrees in area ‘b’, and a taper angle of about 10.3 degrees in area ‘c’. Surface scattering or diffuse reflection may vary (or be different from each other) according to the shape of the light blocking structure BM_C. For example, a diffuse reflection area may be generated by a first width D1 in the first sub-pixel SPXL1_C, a diffuse reflection area may be generated by a second width D2 in the second sub-pixel SPXL2_C, and a diffuse reflection area may be generated by a third width D3 in the third sub-pixel SPXL3_C. For example, a width of the diffuse reflection area in the first sub-pixel SPXL1_C may be the first width D1, a width of the diffuse reflection area in the second sub-pixel SPXL2_C may be the second width D2, and a width of the diffuse reflection area in the third sub-pixel SPXL3_C may be the third width D3.

The space between the organic patterns OLP may be filled with the color filter CF to form the light blocking structure BM of the display device (or pixel PXL) of FIG. 3. Accordingly, the upper surface of the color filter CF may become flat in the emission area EMA and the non-emission area NEA, and the light scattering (or surface scattering) due to the step difference between the light blocking structure BM and the corresponding color filter CF0 may be controlled.

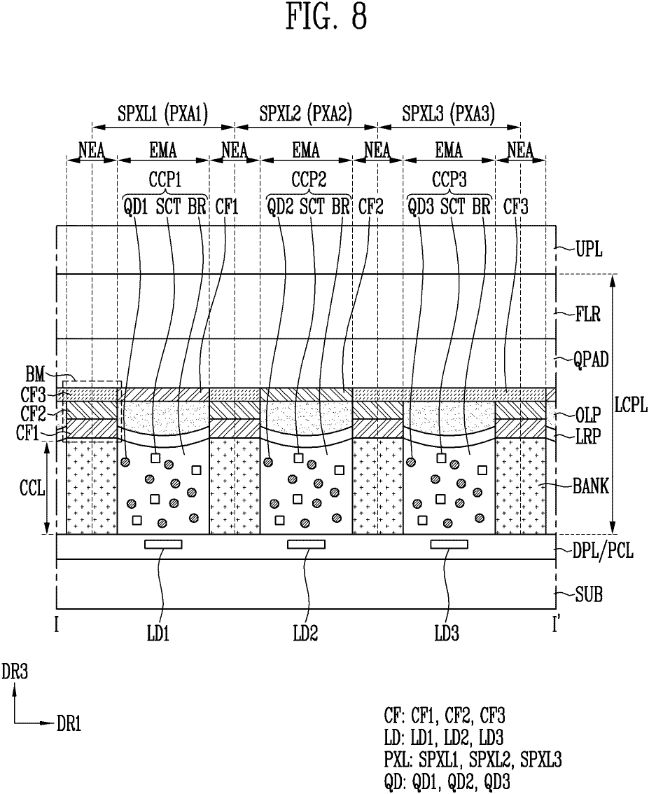

FIG. 8 is a schematic cross-sectional view illustrating another embodiment of the display device of FIG. 1. FIG. 8 schematically shows the pixel PXL taken along line I-I′ of FIG. 1.

Referring to FIGS. 1 to 3 and 8, the display device of FIG. 8 may be substantially the same as or similar to the display device of FIG. 3 except for an organic layer QPAD, an adhesive layer FRL, and an upper substrate UPL. Therefore, a substantially identical or similar description is not repeated.

The organic layer QPAD may be disposed on a color filter CF. The organic layer QPAD may be provided over first, second, and third sub-pixels SPXL1, SPXL2, and SPXL3. The organic layer QPAD may cover a lower member including the color filter CF.

The organic layer QPAD may include at least one organic material such as acrylates resin, epoxy resin, phenolic resin, polyamides resin, polyimides resin, polyester resin, polyphenylenesulfides resin, and benzocyclobutene (BCB), but is not limited thereto.

The upper substrate UPL may be disposed on the organic layer QPAD. An adhesive layer FLR (or filler) may be disposed between the organic layer QPAD and an upper substrate UPL. For example, the upper substrate UPL may be disposed on the organic layer QPAD through an adhesion process using the adhesive layer FRL.

The upper substrate UPL may be a rigid or flexible substrate (or film). In an embodiment, in case that the upper substrate UPL is a rigid substrate, the upper substrate UPL may be at least one of a glass substrate, a quartz substrate, a glass ceramic substrate, and a crystalline glass substrate. In another embodiment, in case that the upper substrate UPL is a flexible substrate, the upper substrate UPL may be at least one of a film substrate and a plastic substrate including a polymer organic material. The upper substrate UPL may include fiber glass reinforced plastic (FRP).

FIG. 9 is a schematic cross-sectional view illustrating an example of the display element layer and the pixel circuit layer included in the display device of FIG. 2.

In FIG. 9, a sub-pixel SPXL is simplified, such as showing each electrode as a single layer electrode and each insulating layer as only a single layer insulating layer, but the disclosure is not limited thereto.

In an embodiment of the disclosure, “connection” between two configurations may mean that both an electrical connection and a physical connection are used inclusively.

Referring to FIGS. 1 to 4 and 9, each sub-pixel SPXL may include the pixel circuit layer PCL and the display element layer DPL disposed on the substrate SUB.

For convenience, the pixel circuit layer PCL is described first, and then the display element layer DPL is described.

The pixel circuit layer PCL may include a buffer layer BFL, a transistor T, and a protection layer PSV.

The buffer layer BFL may be provided and/or formed on the substrate SUB, and may prevent an impurity from diffusing into the transistor T. The buffer layer BFL may be an inorganic insulating layer including an inorganic material. The buffer layer BFL may include at least one metal oxide such as silicon nitride (SiNₓ), silicon oxide (SiOₓ), silicon oxynitride (SiOₓN_{y}), and aluminum oxide (AlOₓ). The buffer layer BFL may be provided as a single layer, or may be provided as multiple layers of at least a double layer. In case that the buffer layer BFL is provided as multiple layers, each layer of the multiple layers may be formed of a same material or different materials. The buffer layer BFL may be omitted according to a material, a process condition, and the like of the substrate SUB.

The transistor T may be a driving transistor that controls a driving current provided to the light emitting element LD. However, the disclosure is not limited thereto, and the transistor T may be a switching transistor that transmits a signal to the driving transistor or performs another function in addition to the driving transistor.

The transistor T may include a semiconductor pattern SCL, a gate electrode GE, a first terminal SE, and a second terminal DE. The first terminal SE may be one of a source electrode and a drain electrode, and the second terminal DE may be the other of the source electrode and the drain electrode. For example, in case that the first terminal SE is a source electrode, the second terminal DE may be a drain electrode.

The semiconductor pattern SCL may be provided and/or formed on the buffer layer BFL. The semiconductor pattern SCL may include a first contact region contacting the first terminal SE and a second contact region contacting the second terminal DE. A region of the semiconductor pattern SCL between the first contact region and the second contact region may be a channel region. The channel region may overlap the gate electrode GE of the corresponding transistor T in a plan view. The semiconductor pattern SCL may be a semiconductor pattern formed of amorphous silicon, poly silicon, low temperature poly silicon, an oxide semiconductor, and an organic semiconductor. However, the disclosure is not limited thereto. For example, the channel region of the semiconductor pattern SCL may be a semiconductor pattern that is not doped with an impurity, and may be an intrinsic semiconductor. The first contact region and the second contact region of the semiconductor pattern SCL may be semiconductor patterns doped with an impurity.

The gate electrode GE may be provided and/or formed on a gate insulating layer GI to correspond to the channel region of the semiconductor pattern SCL. The gate electrode GE may be provided on the gate insulating layer GI and may overlap the channel region of the semiconductor pattern SCL in a plan view. The gate electrode GE may be formed in a single layer of at least one material selected from the group consisting of copper (Cu), molybdenum (Mo), tungsten (W), aluminum neodymium (AlNd), titanium (Ti), aluminum (Al), and silver (Ag). In an embodiment, the gate electrode GE may include an alloy thereof or a mixture thereof. The gate electrode GE may be formed in a double layer or multi-layer structure of at least one of molybdenum (Mo), titanium (Ti), copper (Cu), aluminum (Al), and silver (Ag), which is a low-resistance material, to reduce a line resistance.

The gate insulating layer GI may be an inorganic insulating layer including an inorganic material. For example, the gate insulating layer GI may include at least one metal oxide such as silicon nitride (SiNₓ), silicon oxide (SiOₓ), silicon oxynitride (SiOₓN_{y}), and aluminum oxide (AlOₓ). However, the material of the gate insulating layer GI is not limited to the above-described embodiments, and various materials providing insulation (e.g., electrical insulation) to the gate insulating layer GI may be applied according to an embodiment. For example, the gate insulating layer GI may be formed of an organic insulating layer including an organic material. The gate insulating layer GI may be provided as a single layer, but may also be provided as multiple layers of at least a double layer.

Each of the first terminal SE and the second terminal DE may be provided and/or formed on the second interlayer insulating layer ILD2, and may be in contact with the first contact region and the second contact region of the semiconductor pattern SCL through a contact hole passing through the gate insulating layer GI and first and second interlayer insulating layers ILD1 and ILD2. For example, the first terminal SE may be in contact with the first contact region of the semiconductor pattern SCL, and the second terminal DE may be in contact with the second contact region of the semiconductor pattern SCL. Each of the first and second terminals SE and DE may include the same material as the gate electrode GE, or may include one or more materials selected from materials exemplified as a configuration material of the gate electrode GE.

The first interlayer insulating layer ILD1 and the gate insulating layer GI may include a same material, or may include one or more materials selected from materials exemplified as a configuration material of the gate insulating layer GI.

The second interlayer insulating layer ILD2 may be provided and/or formed on the first interlayer insulating layer ILD1. The second interlayer insulating layer ILD2 may be an inorganic insulating layer including an inorganic material or an organic insulating layer including an organic material. According to an embodiment, the second interlayer insulating layer ILD2 and the first interlayer insulating layer ILD1 may include a same material, but the disclosure is not limited thereto. The second interlayer insulating layer ILD2 may be provided as a single layer, or may be provided as multiple layers of at least a double layer. According to an embodiment, the second interlayer insulating layer ILD2 may be omitted.

In the above-described embodiment, the first and second terminals SE and DE of the transistor T may be separate electrodes electrically connected to the semiconductor pattern SCL through the contact hole sequentially passing through the gate insulating layer GI and the first and second interlayer insulating layers ILD1 and ILD2, but the disclosure is not limited thereto. According to an embodiment, the first terminal SE of the transistor T may be a first contact region adjacent to the channel region of the semiconductor pattern SCL, and the second terminal DE of the transistor T may be a second contact region adjacent to the channel region of the semiconductor pattern SCL. The second terminal DE of the transistor T may be electrically connected to the light emitting element LD of the sub-pixel SPXL through a separate connection means such as a bridge electrode.

The transistor T may be configured of a low temperature polysilicon thin film transistor (LTPS TFT), but the disclosure is not limited thereto. According to an embodiment, the transistors T may be configured of an oxide semiconductor thin film transistor. Although a case in which the transistor T is a thin film transistor of a top gate structure has been described as an example in the above-described embodiment, the disclosure is not limited thereto, and a structure of the transistor T may be variously changed. For example, the transistor T may be a thin film transistor having a bottom gate structure.

The pixel circuit layer PCL may further include a storage capacitor storing a voltage applied between a gate electrode and the first terminal SE (or source electrode) of the transistor T, a driving voltage line providing a driving voltage to the transistor T (or sub-pixel SPXL), and the like.

The protective layer PSV may be provided and/or formed on the transistor T.

The protective layer PSV may be provided in a form including an organic insulating layer, an inorganic insulating layer, or an organic insulating layer disposed on the inorganic insulating layer. The inorganic insulating layer may include for example, at least one metal oxide such as silicon oxide (SiOₓ), silicon nitride (SiNₓ), silicon oxynitride (SiOₓN_{y}), and aluminum oxide (AlOₓ). The organic insulating layer may include, for example, at least one of acrylic resin (polyacrylates resin), epoxy resin, phenolic resin, polyamides resin, polyimide resin, unsaturated polyesters resin, poly-phenylene ethers resin, poly-phenylene sulfides resin, and benzocyclobutene resin.

The display element layer DPL may be provided on the protective layer PSV.

The display element layer DPL may include first and second bank patterns BNP1 and BNP2, first and second pixel electrodes PEL1 and PEL2, the light emitting element LD, and first and second contact electrodes CNE1 and CNE2. The display element layer DPL may include first, second, and third insulating layers INS1, INS2, and INS3.

The first and second bank patterns BNP1 and BNP2 may be positioned in the emission area EMA (refer to FIG. 3) and may be spaced apart from each other. The first and second bank patterns BNP1 and BNP2 may be support members that support each of the first and second pixel electrodes BNP1 and BNP2 to change a surface profile (or shape) of the third direction DR3 of each of the first and second pixel electrodes BNP1 and BNP2. Thus, the first and second bank patterns BNP1 and BNP2 may guide light emitted from the light emitting elements LD in an image display direction (e.g., a front surface direction) of the display device. For example, the first and second bank patterns BNP1 and BNP2 may change the surface profile (or shape) of each of the first and second pixel electrodes PEL1 and PEL2 in the third direction DR3.

The first and second bank patterns BNP1 and BNP2 may be provided and/or formed between the protective layer PSV and a corresponding electrode in the emission area of a corresponding sub-pixel SPXL. For example, the first bank pattern BNP1 may be provided and/or formed between the protective layer PSV and the first pixel electrode PEL1, and the second bank pattern BNP2 may be provided and/or formed between the protective layer PSV and the second pixel electrode PEL2.

The first and second bank patterns BNP1 and BNP2 may be an inorganic insulating layer including an inorganic material or an organic insulating layer including an organic material. According to an embodiment, the first and second bank patterns BNP1 and BNP2 may include a single organic insulating layer and/or a single inorganic insulating layer, but the disclosure is not limited thereto. According to an embodiment, the first and second bank patterns BNP1 and BNP2 may be provided in a form of multiple layers in which at least one organic insulating layer and at least one inorganic insulating layer are stacked. However, the material of the first and second bank patterns BNP1 and BNP2 is not limited to the above-described embodiments, and according to an embodiment, the first bank pattern BNP1 may include a conductive material.

The first and second bank patterns BNP1 and BNP2 may have a trapezoidal-shaped cross-section in which a width becomes narrower from a surface (e.g., an upper surface) of the protective layer PSV toward an upper portion in the third direction DR3, but the disclosure is not limited thereto. According to an embodiment, the first and second bank patterns BNP1 and BNP2 may include a curved surface having a cross-section of a semi-elliptical shape, a semi-circular shape (or a hemispherical shape). In a cross-sectional view, the shape of the first and second bank patterns BNP1 and BNP2 is not limited to the above-described embodiments, and may be variously changed within a range capable of improving efficiency of the light emitted from each of the light emitting elements LD. The first and second bank patterns BNP1 and BNP2 adjacent in the first direction DR1 may be disposed on the same surface of the protective layer PSV, and may have a same height (or thickness) in the third direction DR3.

In the above-described embodiment, the first and second bank patterns BNP1 and BNP2 may be provided and/or formed on the protective layer PSV, and thus the first and second bank patterns BNP1 and BNP2 and the protective layer PSV may be formed by different processes, but the disclosure is not limited thereto. According to an embodiment, the first and second bank patterns BNP1 and BNP2 and the protective layer PSV may be formed through a same process. The first and second bank patterns BNP1 and BNP2 may be a region of the protective layer PSV.

The first and second pixel electrodes PEL1 and PEL2 may be provided and/or formed on the first and second bank patterns BNP1 and BNP2 corresponding thereto.

Each of the first and second pixel electrodes PEL1 and PEL2 may be formed of a material having a reflectance (e.g., a predetermined or selected reflectance) in order to allow the light emitted from the light emitting element LD to proceed in the image display direction of the display device. Each of the first and second pixel electrodes PEL1 and PEL2 may be formed of a conductive material having a reflectance. The conductive material of each of the first and second pixel electrodes PEL1 and PEL2 may include an opaque metal advantageous for reflecting the light emitted from the light emitting element LD in the image display direction of the display device. The opaque metal of each of the first and second pixel electrodes PEL1 and PEL2 may include, for example, at least one metal such as silver (Ag), magnesium (Mg), aluminum (Al), platinum (Pt), palladium (Pd), gold (Au), nickel (Ni), neodymium (Nd), iridium (Ir), chromium (Cr), and titanium (Ti). In an embodiment, the opaque metal of each of the first and second pixel electrodes PEL1 and PEL2 may include an alloy thereof. According to an embodiment, each of the first and second pixel electrodes PEL1 and PEL2 may include a transparent conductive material. The transparent conductive material of each of the first and second pixel electrodes PEL1 and PEL2 may include at least one conductive oxide such as indium tin oxide (ITO), indium zinc oxide (IZO), zinc oxide (ZnOₓ), indium gallium zinc oxide (IGZO), and indium tin zinc oxide (ITZO). In an embodiment, the transparent conductive material of each of the first and second pixel electrodes PEL1 and PEL2 may include a conductive polymer such as poly(3,4-ethylenedioxythiophene) (PEDOT), and the like.

In case that each of the first and second pixel electrodes PEL1 and PEL2 includes a transparent conductive material, a separate conductive material formed of an opaque metal for reflecting the light emitted from the light emitting element LD in the image display direction of the display element layers may be added. However, the material of each of the first and second pixel electrodes PEL1 and PEL2 is not limited to the above-described materials.

Each of the first and second pixel electrodes PEL1 and PEL2 may be provided and/or formed as a single layer, but the disclosure is not limited thereto. According to an embodiment, each of the first and second pixel electrodes PEL1 and PEL2 may be provided and/or formed as multiple layers in which at least two or more materials among metals, alloys, conductive oxides, and conductive polymers are stacked. Each of the first and second pixel electrodes PEL1 and PEL2 may be formed of multiple layers of at a double layer or more to minimize distortion due to a signal delay for transmitting a signal (or voltage) to ends (e.g., both ends) of each of the light emitting elements LD. For example, each of the first and second pixel electrodes PEL1 and PEL2 may be formed in multiple layers in which indium tin oxide (ITO)/silver (Ag)/indium tin oxide (ITO) are sequentially stacked.

According to an embodiment, the first pixel electrode PEL1 may be electrically connected to the transistor T through a first contact hole passing through the protective layer PSV, and the second pixel electrode PEL2 may be electrically connected to a driving voltage line of the pixel circuit layer PCL through a second contact hole passing through the protective layer PSV.

Each of the first pixel electrode PEL1 and the second pixel electrode PEL2 may receive an alignment signal (or alignment voltage) from a corresponding partial configuration of the pixel circuit layer PCL and may be used as an alignment electrode (or alignment line) for aligning the light emitting elements LD. For example, the first pixel electrode PEL1 may receive a first alignment signal (or first alignment voltage) from a partial configuration of the pixel circuit layer PCL and may be used as a first alignment electrode (or first alignment line). The second pixel electrode PEL2 may receive a second alignment signal (or second alignment voltage) from another configuration of the pixel circuit layer PCL and may be used as a second alignment electrode (or second alignment line).

After the light emitting element LD is aligned in the sub-pixel SPXL, a portion of the first pixel electrode PEL1 positioned between adjacent sub-pixels SPXL may be removed to individually (or independently) drive the sub-pixel SPXL.

After the light emitting element LD is aligned, the first pixel electrode PEL1 and the second pixel electrode PEL2 may be used as driving electrodes for driving the light emitting elements LD.

The light emitting element LD may be an ultra-small light emitting diode, for example, having a size as small as a nanometer-scale to a micrometer-scale using a material of an inorganic crystal structure. For example, the light emitting element LD may include a first semiconductor layer, a second semiconductor layer, an active layer, and an insulating layer. The first semiconductor layer of the light emitting element LD may include a semiconductor layer having a type (e.g., a predetermined or selected type), and the second semiconductor layer of the light emitting element LD may include a semiconductor layer of a type different from that of the first semiconductor layer. For example, the first semiconductor layer of the light emitting element LD may include an N-type semiconductor layer, and the second semiconductor layer of the light emitting element LD may include a P-type semiconductor layer. The first semiconductor layer and the second semiconductor layer of the light emitting element LD may include at least one semiconductor material of InAlGaN, GaN, AlGaN, InGaN, AlN, and InN. The active layer of the light emitting element LD may be positioned between the first semiconductor layer and the second semiconductor layer, and may have a single or multiple quantum well structure. In case that an electric field greater than or equal to a voltage is applied to the ends (e.g., both ends) of the light emitting element LD, an electron-hole pair may be combined in the active layer and light may be emitted therefrom.

At least two to tens of light emitting elements LD may be arranged and/or provided in the emission area EMA, but the number of light emitting elements LD arranged and/or provided in the emission area EMA is not limited thereto. According to an embodiment, the number of light emitting elements LD arranged and/or provided in the emission area EMA may be variously changed.

Each of the light emitting elements LD may emit any one of color light and/or white light. In an embodiment, each of the light emitting elements LD may emit blue light of a short wavelength band, but the disclosure is not limited thereto.

The first insulating layer INS1 may be provided and/or formed on the first and second pixel electrodes PEL1 and PEL2.

The first insulating layer INS1 may include an inorganic insulating layer formed of an inorganic material or an organic insulating layer formed of an organic material. The first insulating layer INS1 may be formed of an inorganic insulating layer advantageous for protecting the light emitting element LD from the pixel circuit layer PCL of the sub-pixel SPXL. For example, the first insulating layer INS1 may include at least one metal oxide such as silicon nitride (SiNₓ), silicon oxide (SiOₓ), silicon oxynitride (SiOₓN_{y}), and aluminum oxide (AlOₓ), but the disclosure is not limited thereto. According to an embodiment, the first insulating layer INS1 may be formed of an organic insulating layer advantageous for planarizing a support surface of the light emitting elements LD.

The first insulating layer INS1 may include a first opening OPN1 exposing a region of the first pixel electrode PEL1 and a second opening OPN2 exposing a region of the second pixel electrode PEL2. The first insulating layer INS1 may cover remaining regions except for the region of each of the first and second pixel electrodes PEL1 and PEL2. For example, the first opening OPN1 and the second opening OPN2 of the first insulating layer INS1 may expose the regions corresponding to the first and second openings OPN1 and OPN2. The light emitting elements LD may be disposed (or aligned) on the first insulating layer INS1 between the first pixel electrode PEL1 and the second pixel electrode PEL2.

The second insulating layer INS2 (or second insulating pattern) may be provided and/or formed on the light emitting element LD. The second insulating layer INS2 may be provided and/or formed on the light emitting element LD to partially cover an outer circumferential surface (or surface) of the light emitting element LD. The active layer of the light emitting element LD may not be in contact with an external conductive material by the second insulating layer INS2. The second insulating layer INS2 may cover only a portion of a surface (e.g., outer peripheral surface) of the light emitting element LD to expose the ends (e.g., both ends) of the light emitting element LD to the outside. The second insulating layer INS2 may be formed as an insulating pattern independent of (or separated from) the sub-pixel SPXL, but the disclosure is not limited thereto.

The second insulating layer INS2 may be configured of a single layer or multiple layers, and may include an inorganic insulating layer including at least one inorganic material or an organic insulating layer including at least one organic material. According to a design condition or the like of the display device, to which the light emitting element LD is applied, the second insulating layer INS2 may be formed of an inorganic insulating layer including an inorganic material or an organic insulating layer including an organic material. After the alignment of the light emitting element LD in the sub-pixel SPXL is completed, the second insulating layer INS2 may be formed on the light emitting element LD to prevent the light emitting element LD from being separated from an aligned position.

The first contact electrode CNE1 may be provided on the first pixel electrode PEL1 to be in contact with or to be connected to the first pixel electrode PEL1 through the first opening OPN1 of the first insulating layer INS1. According to an embodiment, in case that a capping layer (not shown) is disposed on the first pixel electrode PEL1, the first contact electrode CNE1 may be disposed on the capping layer and may be electrically connected to the first pixel electrode PEL1 through the capping layer. The above-described capping layer may protect the first pixel electrode PEL1 from a defect generated during a manufacturing process of the display device, and may further strengthen (or increase) adhesion force between the first pixel electrode PEL1 and the pixel circuit layer PCL positioned thereunder. The capping layer may include a transparent conductive material (or substance) such as indium zinc oxide (IZO).

The first contact electrode CNE1 may be provided and/or formed on an end of the light emitting element LD to be electrically connected to the end of the light emitting element LD. Accordingly, the first pixel electrode PEL1 and an end of the light emitting element LD may be electrically connected to each other through the first contact electrode CNE1.

Similar to the first contact electrode CNE1, the second contact electrode CNE2 may be provided on the second pixel electrode PEL2, and be in contact with or be electrically connected to the second pixel electrode PEL2 through the second opening OPN2 of the first insulating layer INS1. According to an embodiment, in case that a capping layer is disposed on the second pixel electrode PEL2, the second contact electrode CNE2 may be disposed on the capping layer and may be electrically connected to the second pixel electrode PEL2 through the capping layer. The second contact electrode CNE2 may be provided and/or formed on another end of the light emitting element LD, and be electrically connected to the another end of the light emitting element LD. Accordingly, the second pixel electrode PEL2 and the another end of the light emitting element LD may be electrically connected to each other through the second contact electrode CNE2.

The first and second contact electrodes CNE1 and CNE2 may be formed of various transparent conductive materials, and light emitted from the light emitting element LD and reflected by the first and second pixel electrodes PEL1 and PEL2 may proceed in the image display direction of the display device without loss. For example, the first and second contact electrodes CNE1 and CNE2 may include at least one transparent conductive material (or substance) of indium tin oxide (ITO), indium zinc oxide (IZO), zinc oxide (ZnOₓ), indium gallium zinc oxide (IGZO), and indium tin zinc oxide (ITZO). However, the disclosure is not limited thereto. The first and second contact electrodes CNE1 and CNE2 may be substantially transparent or translucent to satisfy a light transmittance (e.g., a predetermined or selected light transmittance). For example, the first and second contact electrodes CNE1 and CNE2 may be substantially transparent to have transmittance of about 80% or more, or about 90% or more.

However, the material of the first and second contact electrodes CNE1 and CNE2 is not limited to the above-described embodiment. According to an embodiment, the first and second contact electrodes CNE1 and CNE2 may be formed of various opaque conductive materials (or substances). The first and second contact electrodes CNE1 and CNE2 may be formed of a single layer or multiple layers.

A shape of the first and second contact electrodes CNE1 and CNE2 may not be limited, and may be variously changed within a range electrically and stably connected to the light emitting element LD. The shape of the first and second contact electrodes CNE1 and CNE2 may be variously changed in consideration of a connection relationship with electrodes disposed thereunder.

The first and second contact electrodes CNE1 and CNE2 may be disposed to be spaced apart from each other in the first direction DR1. For example, the first contact electrode CNE1 and the second contact electrode CNE2 may be disposed to be spaced apart from each other with a distance (e.g., a predetermined or selected distance) therebetween on the second insulating layer INS2. The first contact electrode CNE1 and the second contact electrode CNE2 may be provided on a same layer and formed through a same process. However, the disclosure is not limited thereto, and according to an embodiment, the first and second contact electrodes CNE1 and CNE2 may be provided on different layers and may be formed through different processes.

The third insulating layer INS3 may be provided and/or formed on the first and second contact electrodes CNE1 and CNE2. The third insulating layer INS3 may be an inorganic insulating layer including an inorganic material or an organic insulating layer including an organic material. For example, the third insulating layer INS3 may have a structure in which at least one inorganic insulating layer or at least one organic insulating layer is alternately stacked. The third insulating layer INS3 may cover (e.g., entirely cover) the display element layer DPL to prevent water or moisture from flowing into the display element layer DPL including the light emitting elements LD from the outside.

FIG. 10 is a schematic cross-sectional view illustrating another example of the display element layer and the pixel circuit layer included in the display device of FIG. 2.

Referring to FIGS. 1 to 4, 9, and 10, a sub-pixel SPXL may include a pixel circuit layer PCL and a display element layer DPL_1 disposed on a substrate SUB. Since the substrate SUB and the pixel circuit layer PCL are described with reference to FIG. 9, a substantially identical or similar description is not repeated.

The display element layer DPL_1 may include a pixel defining layer PDL and a light emitting element LD_1. The light emitting element LD_1 may include a first electrode AE, an emission layer EML, and a second electrode CE. For example, the light emitting element LD_1 may be an organic light emitting diode.

The first electrode AE may be disposed on a protective layer PSV. The first electrode AE may be electrically connected to a transistor T through a contact hole passing through the protective layer PSV.

The pixel defining layer PDL may include an opening, and at least a portion of the first electrode AE may be exposed through the opening. According to an embodiment, the pixel defining layer PDL may be omitted. The pixel defining layer PDL may include an organic material.

The emission layer EML may be disposed on the first electrode AE, and the second electrode CE may be disposed on the emission layer EML.

One of the first electrode AE and the second electrode CE may be an anode electrode, and another thereof may be a cathode electrode. For example, the first electrode AE may be the anode electrode, and the second electrode CE may be the cathode electrode.

At least one of the first electrode AE and the second electrode CE may be a transmissive electrode. For example, in case that the display device is a front surface emission type display device, the first electrode AE may be a reflective electrode and the second electrode CE may be a transmissive electrode.

The emission layer EML may be disposed on an exposed surface of the first electrode AE. The emission layer EML may have a multilayer thin film structure including at least a light generation layer. For example, the emission layer EML may include a hole injection layer that injects a hole, a hole transport layer having desired (or excellent) hole transport properties and for increasing a chance of recombination of a hole and an electron by suppressing a movement of an electron that is not combined in the light generation layer, the light generation layer that emits light by the recombination of the injected electron and hole, a hole blocking layer for suppressing a movement of a hole that is not combined in the light generation layer, an electron transport layer for smoothly transporting the electron to the light generation layer, and an electron injection layer for injecting the electron.

The hole injection layer, the hole transport layer, the hole blocking layer, the electron transport layer, and the electron injection layer may be a common layer electrically connected in pixel parts adjacent to each other.

The second electrode CE may be disposed on the emission layer EML. The second electrode CE may be a transflective reflective layer. For example, the second electrode CE may be a thin metal layer having a thickness sufficient to transmit light. The second electrode CE may transmit some of light generated in the light generation layer and reflect remaining some (or rest) of the light generated in the light generation layer.

Some of light emitted from the emission layer EML may not transmit the second electrode CE, and light reflected from the second electrode CE may be reflected from the first electrode AE again. For example, the light emitted from the emission layer EML may resonate between the first electrode AE and the second electrode CE. Light extraction efficiency of the light emitting element LD may be improved by resonance of light.

The display element layer DPL_1 may further include a thin film encapsulation layer TFE.

The thin film encapsulation layer TFE may be disposed on the second electrode CE. The thin film encapsulation layer TFE may be disposed (e.g., commonly disposed) on the sub-pixels SPX. The thin film encapsulation layer TFE may cover (e.g., directly cover) the second electrode CE.

The thin film encapsulation layer TFE may include a first encapsulation inorganic layer IOL1, a first encapsulation organic layer OL1, and a second encapsulation inorganic layer IOL2, which are sequentially stacked on the second electrode CE. Each of the first encapsulation inorganic layer IOL1 and the second encapsulation inorganic layer IOL2 may be formed of at least one inorganic insulating material such as polysiloxane, silicon nitride, silicon oxide, and silicon oxynitride. The encapsulation organic layer may be formed of at least one organic insulating material such as a polyacrylic compound, a polyimide compound, a fluorine carbon compound such as Teflon, and a benzocyclobutene compound.

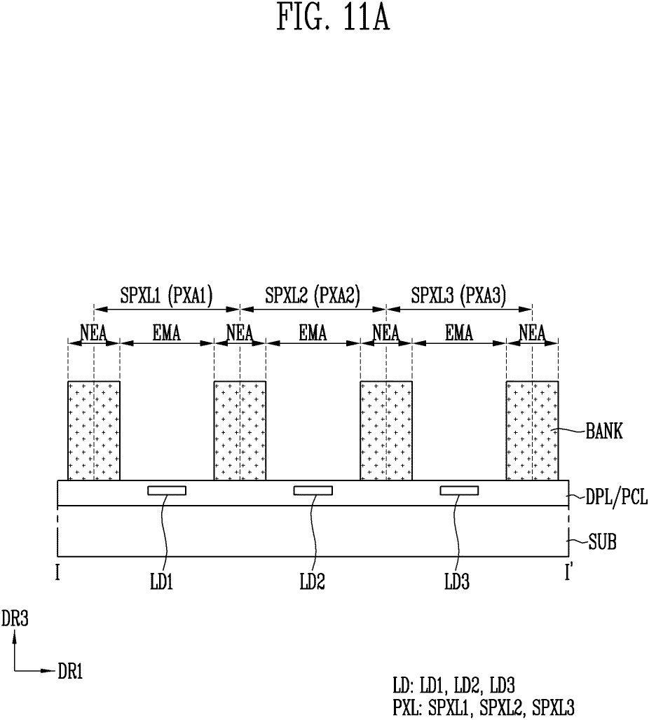

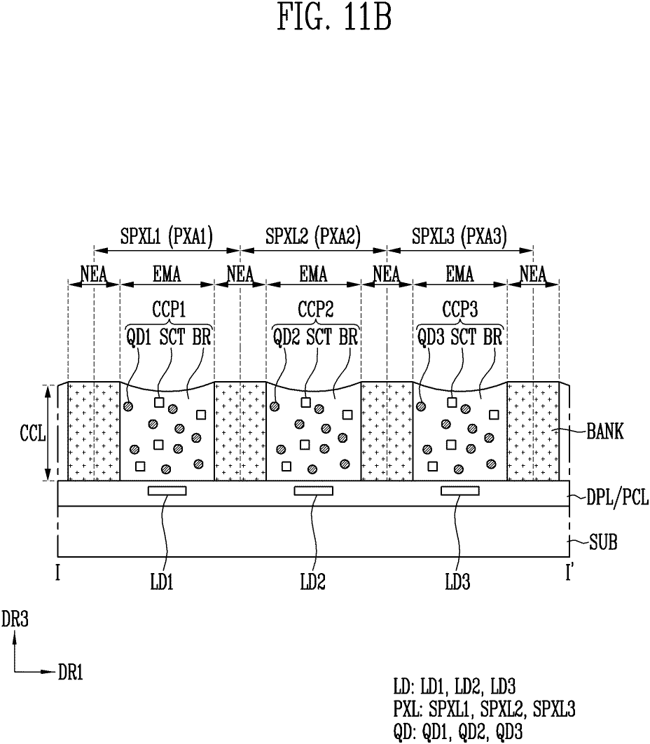

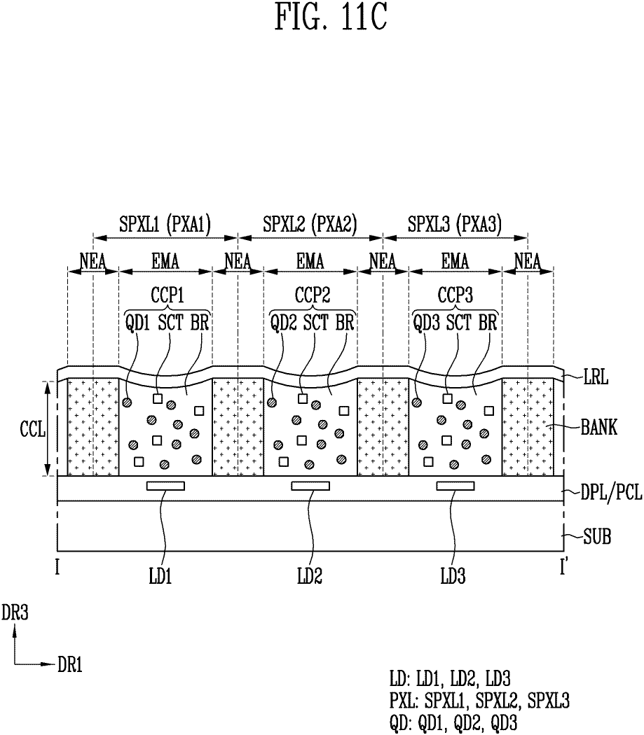

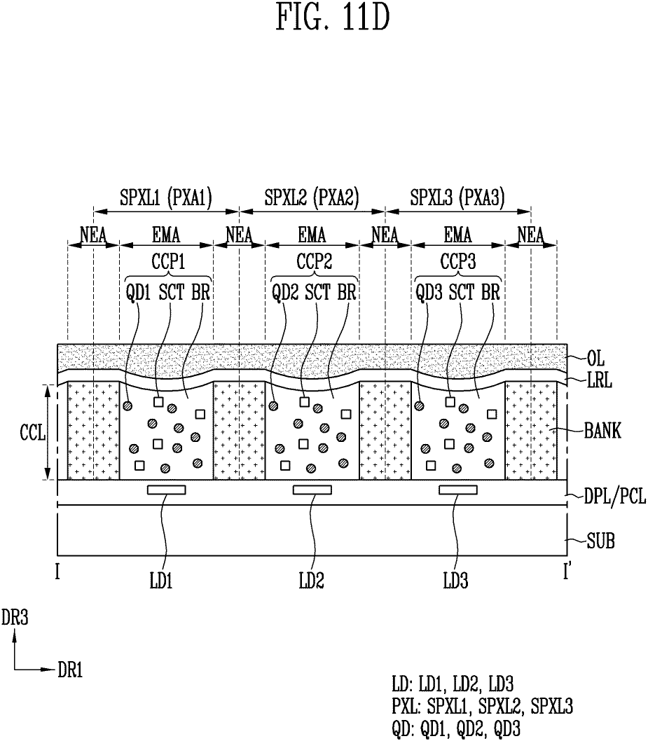

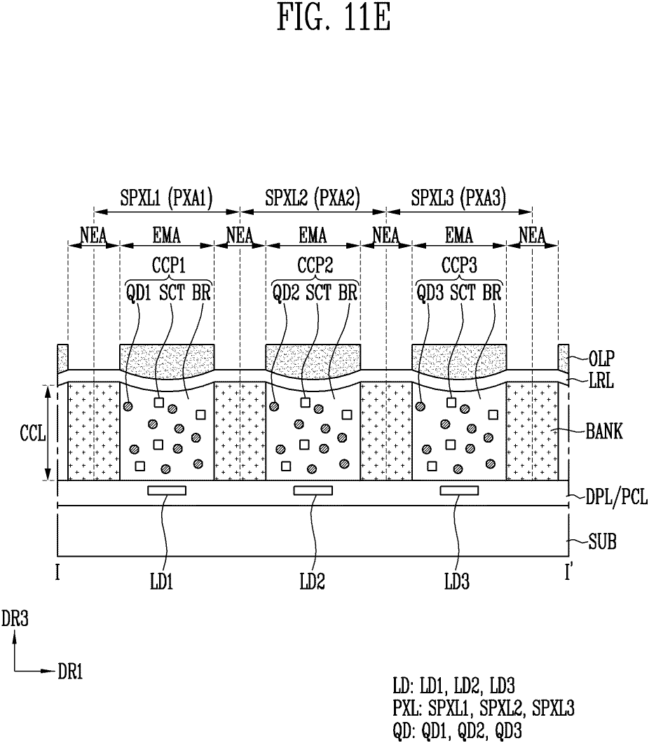

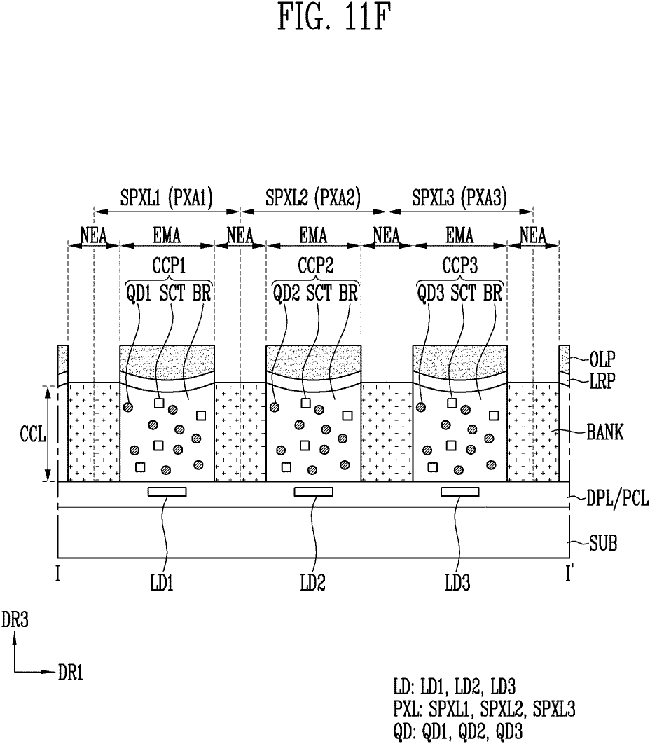

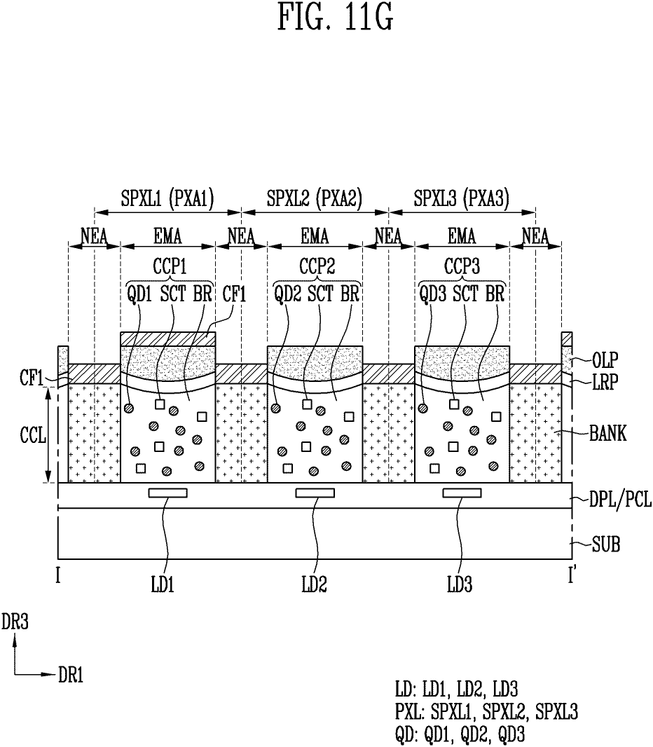

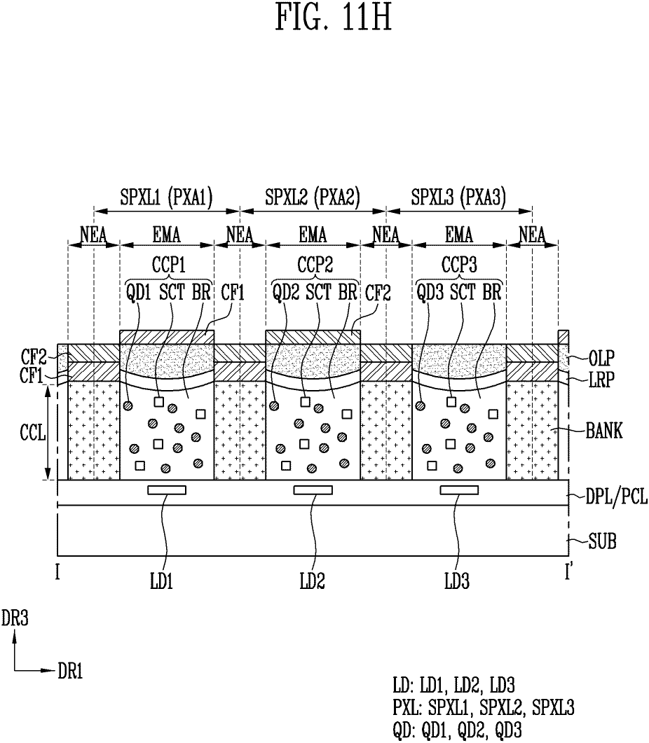

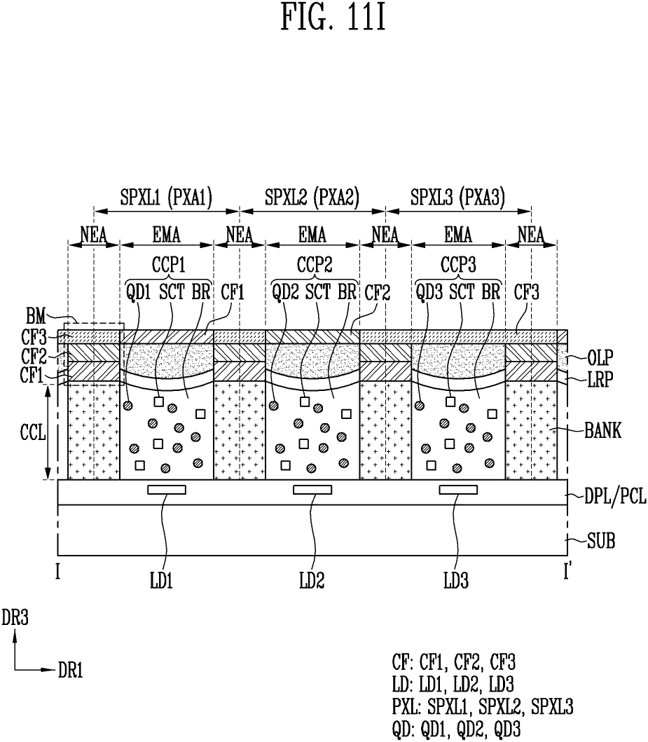

FIGS. 11A to 11I are schematic diagrams illustrating a method of manufacturing the display device of FIG. 3.

First, referring to FIGS. 1 to 3 and 11A, a panel in which the pixel circuit layer PCL and the display element layer DPL are disposed on the substrate SUB may be prepared. The light emitting element LD of the display element layer DPL may be disposed in the emission area EMA of the substrate SUB.

The bank BANK may be formed in the non-emission area NEA of the substrate SUB. For example, the bank BANK may be formed on the display element layer DPL, but is not limited thereto. The bank BANK may include openings corresponding to the emission area EMA.

Referring to FIG. 11B, the first, second, and third color conversion patterns CCP1, CCP2, and CCP3 may be formed in the openings of the bank BANK.

For example, the first color conversion pattern CCP1 may be supplied and formed in the emission area EMA of the first sub-pixel SPXL1. The second color conversion pattern CCP2 may be supplied and formed in the emission area EMA of the second sub-pixel SPXL2. The third color conversion pattern CCP3 may be supplied and formed in the emission area EMA of the third sub-pixel SPXL3. For example, the first color conversion pattern CCP1, the second color conversion pattern CCP2, and the third color conversion pattern CCP3 may be supplied and formed by using inkjet printing technology.

Referring to FIG. 11C, the low refractive layer LRL may be formed on the color conversion layer CCL including the bank BANK and the first, second, and third color conversion patterns CCP1, CCP2, and CCP3.

The low refractive layer LRL may be formed (e.g., entirely formed) on the substrate SUB to cover the color conversion layer CCL. For example, the low refractive layer LRL may cover the bank BANK and the first, second, and third color conversion patterns CCP1, CCP2, and CCP3.

In an embodiment, a first inorganic layer may be disposed between the color conversion layer CCL and the low refractive layer LRL to form the first capping layer CAP 1 (or first capping pattern) described with reference to FIG. 4. A second inorganic layer may be formed on the low refractive layer LRL to form the second capping layer CAP2 (or second capping pattern). For example, in a process of forming the low refractive layer LRL, at least one inorganic layer may be formed.

Referring to FIG. 11D, the organic layer OL may be formed on the low refractive layer LRL. The organic layer OL may be formed on (e.g., formed entirely on) the substrate SUB to cover the low refractive layer LRL. The organic layer OL may provide a flat upper surface for forming the color filter CF (e.g., refer to FIG. 3).

Referring to FIG. 11E, a portion of the organic layer OL (e.g., refer to FIG. 11D) overlapping the non-emission area NEA in a plan view may be removed to form the organic pattern OLP. For example, the organic pattern OLP may be formed through a photo process (or etching process) using a mask.

Referring to FIG. 11F, a portion of the low refractive layer LRL (e.g., refer to FIG. 11E) overlapping the non-emission area NEA in a plan view may be removed to form the low refractive pattern LRP. For example, the organic pattern OLP and the low refractive pattern LRP may be formed using the mask or through a same etching process.

In case that the second inorganic layer is formed on the low refractive layer LRL (e.g., refer to FIG. 11E), the second inorganic layer may be partially etched together with the low refractive layer LRL. The second capping layer CAP2 (or second capping pattern) described with reference to FIG. 4 may be formed. Similarly, in case that the first inorganic layer is formed under the low refractive layer LRL, the first inorganic layer may be partially etched together with the low refractive layer LRL. The first capping layer CAP1 (or first capping pattern) described with reference to FIG. 4 may be formed.

For reference, a pad (not illustrated) for connection (or signal transmission) to an external device may be formed in the non-display area NDA shown in FIG. 1, and an etching process may be performed on the organic layer OL (e.g., refer to FIG. 11D) and the low refractive layer LRL (e.g., refer to FIG. 11D) to form the pad on the pixel circuit layer PCL and/or the display element layer DPL. In the etching process, the organic pattern OLP and the low refractive pattern LRP may be formed. For example, the organic pattern OLP and the low refractive pattern LRP may be formed without adding a separate process (using etching process for forming the pad).

Referring to FIGS. 11G, 11H, and 11I, the color filter CF may be formed on the bank BANK and the organic pattern OLP.

For example, the first color filter CF1 may be formed or patterned in the non-emission area NEA and the emission area EMA of the first sub-pixel SPXL1. Thereafter, the second color filter CF2 may be formed or patterned in the non-emission area NEA and the emission area EMA of the second sub-pixel SPXL2. Thereafter, the third color filter CF3 may be formed or patterned in the non-emission area NEA and the emission area EMA of the third sub-pixel SPXL3. In the non-emission area NEA, the first, second, and third color filters CF1, CF2, and CF3 may be filled in a form in which the first, second, and third color filters CF1, CF2, and CF3 are sequentially stacked in the space (or valley) between the organic patterns OLP. The first, second, and third color filters CF1, CF2, and CF3 sequentially stacked in the non-emission area NEA may configure the light blocking structure BM (or light blocking pattern).

The light blocking structure BM (or color filter CF) may prevent the light generated in the sub-pixel (e.g., the second sub-pixel) from proceeding to the adjacent sub-pixel (e.g., the first sub-pixel SPXL1 and the third sub-pixel SPXL3) through the low refractive pattern LRP and the organic pattern OLP. The light blocking structure BM may prevent side surfaces of the low refractive pattern LRP and the organic pattern OLP (or side surfaces of the organic layer OL_C and the light blocking structure BM_C shown in FIG. 6) from being exposed to the outside.

In FIGS. 11G, 11H, and 11I, the first and second color filters CF1 and CF2 are discontinuous between the non-emission area NEA and the emission area EMA, but the disclosure is not limited thereto. For example, the first color filter CF1 may be continuous or integrally formed in the entire first pixel area PXA1 of the first sub-pixel SPXL1 (e.g.,, the first color filter CF1 is not separated in the emission area EMA and the non-emission area NEA of first pixel area PXA1), and the second color filter CF2 may be continuous or integrally formed in the entire second pixel area PXA2 of the second sub-pixel SPXL2.

As shown in FIG. 3, the overcoat layer OC may be formed entirely on the substrate SUB to cover the color filter CF. In other embodiments, as shown in FIG. 8, the organic layer QPAD may be formed entirely on the substrate SUB to cover the color filter CF. The upper substrate UPL may be disposed on the organic layer QPAD. The adhesive layer FLR (or filler) may be filled between the organic layer QPAD and the upper substrate UPL.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
emission areas;
a non-emission area;
light emitting elements disposed on a substrate in the emission areas;
a bank disposed on the substrate in the non-emission area and including openings corresponding to the emission areas;
color conversion patterns disposed in the openings of the bank and converting a wavelength band of light incident from the light emitting elements to emit light;
organic patterns disposed on the color conversion patterns and separated from each other; and
color filters disposed on the organic patterns,
wherein the color filters are sequentially stacked in a space between the organic patterns in the non-emission area.

2. The display device according to claim 1, wherein the color filters sequentially stacked in the non-emission area form a light blocking structure.

3. The display device according to claim 2, wherein the light blocking structure is disposed directly on the bank and contacts the bank.

4. The display device according to claim 2, wherein a height of an upper surface of the light blocking structure and a height of an upper surface of the color filters in the emission areas with respect to the substrate are substantially equal to each other.

5. The display device according to claim 1, further comprising:
inorganic patterns disposed between the color conversion patterns and the organic patterns in the emission areas.

6. The display device according to claim 5, wherein a refractive index of the inorganic patterns is less than a refractive index of the color conversion patterns.

7. The display device according to claim 5, wherein the inorganic patterns are spaced apart from each other and are disposed in the emission areas.

8. The display device according to claim 5, further comprising:
a second capping layer disposed between the inorganic patterns and the organic patterns in the emission areas; and
a first capping layer disposed between the color conversion patterns and the inorganic patterns.

9. The display device according to claim 8, wherein each of the first capping layer and the second capping layer includes patterns spaced apart from each other to correspond to the emission areas.

10. The display device according to claim 1, wherein an average thickness of the organic patterns is greater than half a thickness of one of the color filters and less than or substantially equal to a thickness of two of the color filters.

11. The display device according to claim 1, further comprising:
an overcoat layer disposed on the color filters and overlapping the color filters in a plan view.

12. The display device according to claim 1, further comprising:
an upper substrate disposed on the color filters; and
a filler disposed between the color filters and the upper substrate.

13. The display device according to claim 1, wherein the light emitting elements include inorganic light emitting diodes.

14. The display device according to claim 1, wherein the light emitting elements include organic light emitting diodes.

15. A display device comprising:
an emission area;
a non-emission area surrounding the emission area;
a light emitting element disposed on a substrate in the emission area;
a bank disposed on the substrate in the non-emission area and including an opening corresponding to the emission area;
a color conversion pattern disposed in the opening of the bank and converting a wavelength band of light incident from the light emitting element to emit light;
color filters sequentially stacked on the bank; and
an organic pattern disposed between one of the color filters and the color conversion pattern in the emission area,
wherein an uppermost surface of the color filters is substantially flat in the emission area and the non-emission area.

16. The display device according to claim 15, wherein the organic pattern is disposed in an island shape in the emission area by the color filters.

17. The display device according to claim 15, wherein
the color filters are formed directly on the bank in the non-emission area, and
one of the color filters contacts the bank.

18. The display device according to claim 17, further comprising:
an inorganic pattern disposed between the color conversion pattern and the organic pattern in the emission area.

19. A method of manufacturing a display device, the method comprising:
preparing a panel including:
light emitting elements disposed in emission areas; and
a bank disposed on a substrate in a non-emission area and having openings corresponding to the emission areas;
forming color conversion patterns converting a wavelength band of light incident from the light emitting elements to emit light, in the openings of the bank;
forming an organic layer on the color conversion patterns;
forming organic patterns by etching a portion of the organic layer overlapping the non-emission area; and
forming color filters on the bank and the organic patterns,
wherein the color filters are filled in a form in which the color filters are sequentially stacked in a space between the organic patterns in the non-emission area.

20. The method of claim 19, wherein
the forming of the organic layer comprises:
forming at least one inorganic layer on the color conversion patterns; and
forming the organic layer on the at least one inorganic layer, and
wherein the forming of the organic patterns comprises etching the at least one inorganic layer to form inorganic patterns from the at least one inorganic layer.
